(19) United States
(12) Patent Application Publication
(10) Pub. No.: US 2026/0326570 A1
(43) Pub. Date: Oct. 22, 2026

(54) Controlled DC Link Capacitor Charge and Discharge

(71) Applicant: SEMICONDUCTOR COMPONENTS INDUSTRIES, LLC, Scottsdale, AZ (US)

(72) Inventors: Jeevan THOMAS, Bangalore (IN); Milind DIGHRASKER, Bangalore (IN)

(73) Assignee: SEMICONDUCTOR COMPONENTS INDUSTRIES, LLC, Scottsdale, AZ (US)

(21) Appl. No.: 19/451,311

(22) Filed: Jan. 16, 2026

Related U.S. Application Data
(60) Provisional application No. 63/790,593, filed on Apr. 17, 2025.

(51) Int. Cl. B60L 3/00; B60L 15/08; H02M 1/14; H02M 1/32; H02M 7/5387

(52) U.S. Cl. CPC B60L 3/0007; B60L 15/08; H02M 1/14; H02M 1/322; H02M 7/53871; B60L 2210/42

(57) ABSTRACT

A motor drive system is disclosed. The motor drive system includes a DC link capacitor coupled to a DC voltage bus, an inverter having multiple phases that each include a first switch and a second switch coupled in series between the DC voltage bus and system ground, a first gate driver configured to drive the first switch of a first phase of the inverter in an on-state in response to a discharge command, and a second gate driver including a hysteretic current-control circuit configured to, in response to the discharge command, regulate a discharge current through the second switch of the first phase of the inverter based on a minimum-discharge-current threshold and a maximum-discharge-current threshold.

### PRIORITY

This application claims the benefit of provisional patent application No. 63/790,593, filed Apr. 17, 2025, which is hereby incorporated by reference herein in its entirety.

### TECHNICAL FIELD

The disclosure relates generally to motor drive systems, and particularly to the charge and discharge of a DC link capacitor in a motor drive system.

### BACKGROUND

In electric vehicles, a three-phase inverter system may drive an electric motor to provide the primary motive force of the vehicle. The inverter system may be powered by a high-voltage battery, operating for example at 400 V or 800 V. The inverter system typically employs a large energy storage capacitor, referred to as a DC link capacitor, to maintain a desired bus voltage and to smooth any switching related ripples on the bus line.

A shutdown of the drive system may be initiated by various events, such as a detected crash or a simple turning off of the vehicle. During the shutdown, the high-voltage battery may be isolated from the remainder of the inverter system for safety purposes. However, the DC link capacitor may remain charged at the high voltage. Various safety requirements specify that the high-voltage charge stored on the DC link capacitor must be discharged within a specified time. For example, Federal Motor Vehicle Safety Standards (FMVSS) in the United States require that the voltage on the DC link capacitor must, under certain circumstances, be discharged to less than 60 V within 5 seconds of the shutdown.

Some conventional inverter systems have employed a discharge path through a high-voltage rated transistor coupled in series with high-wattage resistors. Inventors of embodiments of the present disclosure have recognized that such high-voltage rated transistors and high-wattage resistors may be bulky, require thermal management, and add to the cost of manufacturing the system. Other conventional inverter systems have employed a discharge path directly through high-voltage and high-power rated transistors, creating a high-current short-circuit path for a short duration. However, inventors of embodiments of the present disclosure have also recognized that high-current pulses through such discharge transistors may degrade the life of the discharge transistors as this discharge operation is repeated on a regular basis.

Further, in addition to discharging the DC link capacitor in response to a shutdown of the inverter system, the DC link capacitor must be recharged when the inverter system is reenabled, for example when the electric vehicle is started again. Specifically, the DC link capacitor must be pre-charged before being coupled directly to the battery to prevent large, and potentially damaging, in-rush currents. Some conventional inverter systems have employed a pre-charge path through a high-voltage rated transistor coupled in series with high-wattage resistors. Inventors of embodiments of the present disclosure have recognized that such high-voltage rated transistors and high-wattage resistors may be bulky, require thermal management, and add to the cost of manufacturing the system. Other conventional inverter systems have employed a pre-charge path directly through high-voltage and high-power rated transistors, creating a high-current short-circuit path for a short duration. However, inventors of embodiments of the present disclosure have also recognized that high-current pulses through such pre-charge transistors may degrade the life of the pre-charge transistors as this charge operation is repeated on a regular basis. Embodiments of the present disclosure may address one or more of these challenges.

### SUMMARY

The examples herein enable a motor drive system configured to provide a controlled charge and/or discharge of a DC link capacitor.

According to one embodiment, a motor drive system includes a DC link capacitor coupled to a DC voltage bus, an inverter having multiple phases that each include a first switch and a second switch coupled in series between the DC voltage bus and system ground, a first gate driver configured to drive the first switch of a first phase of the inverter in an on-state in response to a discharge command, and a second gate driver including a hysteretic current-control circuit configured to, in response to the discharge command, regulate a discharge current through the second switch of the first phase of the inverter based on a minimum-discharge-current threshold and a maximum-discharge-current threshold. In some embodiments, the hysteretic current-control circuit includes a current-starved pull-up circuit configured to increase a gate voltage of the second switch in response to the discharge current crossing below the minimum-discharge-current threshold, and a current-starved pull-down circuit configured to decrease the gate voltage of the second switch in response to the discharge current crossing above the maximum-discharge-current threshold. In the same or different embodiments, the second switch of the first phase includes a sense-FET configured to provide a sense current representative of the discharge current through the second switch, and the hysteretic current-control circuit includes (i) a current mirror circuit configured to mirror the sense current from the sense-FET of the second switch, (ii) a first comparator configured to compare a first mirrored sense-FET current against a first current threshold corresponding to the minimum-discharge-current threshold, and (iii) a second comparator configured to compare a second mirrored sense-FET current against a second current threshold corresponding to the maximum-discharge-current threshold. In the same or different embodiments, the motor drive system further includes a sense resistor coupled to produce a sense voltage based on a sense current from a sense-FET of the second switch, wherein the hysteretic current-control circuit includes a hysteretic voltage comparator configured to compare the sense voltage against a first voltage threshold corresponding to the minimum-discharge-current threshold and a second voltage threshold corresponding to the maximum-discharge-current threshold. In the same or different embodiments, the motor drive system further includes a sense resistor coupled in series with the second switch to produce a sense voltage proportional to the discharge current, wherein the hysteretic current-control circuit includes a hysteretic voltage comparator configured to compare the sense voltage against a first voltage threshold corresponding to the minimum-discharge-current threshold and a second voltage threshold corresponding to the maximum-discharge-current threshold. In the same or different embodiments, the first gate driver and the second gate driver are configured to respectively drive the first switch and the second switch of the first phase in respective off states in response to a voltage of the DC link capacitor crossing below a discharge threshold. In the same or different embodiments, the motor drive system further includes a monitor circuit configured to record a discharge time required for the discharge current to discharge the DC link capacitor to a discharge threshold for each of a plurality of discharge cycles. In the same or different embodiments, the monitor circuit is further configured to estimate a capacitance of the DC link capacitor based on the discharge current and a recorded discharge time, and to produce an alert in response to change in an estimated capacitance of the DC link capacitor.

According to another embodiment, a control circuit for a motor drive system includes a first gate driver configured to drive a first switch of a first phase of an inverter in an on-state in response to a discharge command, and a second gate driver including a hysteretic current-control circuit configured to, in response to the discharge command, regulate a discharge current through a second switch of the first phase of the inverter based on a minimum-discharge-current threshold and a maximum-discharge current threshold. In some embodiments, the hysteretic current-control circuit includes a current-starved pull-up circuit configured to increase a gate voltage of the second switch in response to the discharge current crossing below the minimum-discharge-current threshold, and a current-starved pull-down circuit configured to decrease the gate voltage of the second switch in response to the discharge current crossing above the maximum-discharge-current threshold. In the same or different embodiments, the hysteretic current-control circuit includes a current mirror circuit configured to mirror a sense current from a sense-FET of the second switch, a first comparator configured to compare a first mirrored sense-FET current against a first current threshold corresponding to the minimum-discharge-current threshold, and a second comparator configured to compare a second mirrored sense-FET current against a second current threshold corresponding to the maximum-discharge-current threshold. In the same or different embodiments, the hysteretic current-control circuit includes a hysteretic voltage comparator configured to compare a sense voltage representative of the discharge current against a first voltage threshold corresponding to the minimum-discharge-current threshold and a second voltage threshold corresponding to the maximum-discharge-current threshold.

A further embodiment includes a method for controlling operation of a motor drive system, the method including receiving a discharge command to discharge a DC link capacitor, driving a first switch of a first phase of an inverter coupled to the DC link capacitor in an on-state, sensing a discharge current through a second switch of the first phase of the inverter, and hysteretically regulating the discharge current through the second switch of the first phase of the inverter based on a minimum-discharge-current threshold and a maximum-discharge current threshold. In some embodiments, hysteretically regulating the discharge current through the second switch comprises increasing a gate voltage of the second switch in response the discharge current crossing below the minimum-discharge-current threshold, and decreasing the gate voltage of the second switch in response to the discharge current crossing above the maximum-discharge-current threshold. In the same or different embodiments, increasing a gate voltage of the second switch comprises driving a gate of the second switch with a current-starved pull-up circuit, and decreasing the gate voltage of the second switch comprises driving the gate of the second switch with a current-starved pull-down circuit. In the same or different embodiments, hysteretically regulating the discharge current through the second switch comprises receiving a sense current representative of the discharge current, comparing a first mirrored sense-FET current against a first current threshold corresponding to the minimum-discharge-current threshold, and comparing a second mirrored sense-FET current against a second current threshold corresponding to the maximum-discharge-current threshold. In the same or different embodiments, hysteretically regulating the discharge current through the second switch comprises receiving a sense voltage representative of the discharge current, and comparing the sense voltage against a first voltage threshold corresponding to the minimum-discharge-current threshold and a second voltage threshold corresponding to the maximum-discharge-current threshold. In the same or different embodiments, the method further comprises driving the first switch and the second switch of the first phase in respective off-states in response to detecting a voltage of the DC link capacitor has crossed below a voltage threshold. In the same or different embodiments, the method further comprises recording a discharge time required to discharge a DC link capacitor to a discharge threshold for each of a plurality of discharging cycles. In the same or different embodiments, the method further comprises estimating a capacitance of the DC link capacitor based on the discharge current and a recorded discharge time, and producing an alert in response to change in an estimated capacitance of the DC link capacitor.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a schematic diagram of a motor drive system in accordance with embodiments of the present disclosure.

FIG. 2 illustrates a schematic diagram of components of a discharge circuit within a motor drive system in accordance with embodiments of the present disclosure.

FIG. 3 illustrates a schematic diagram of components of a discharge circuit within a motor drive system in accordance with embodiments of the present disclosure.

FIG. 4 illustrates plot diagrams of waveforms within a motor drive system in accordance with embodiments of the present disclosure.

FIG. 5 illustrates a schematic diagram of components of a discharge circuit within a motor drive system in accordance with embodiments of the present disclosure.

FIG. 6 illustrates a schematic diagram of components of a discharge circuit within a motor drive system in accordance with embodiments of the present disclosure.

FIG. 7 illustrates a method for controlling operation of a motor drive system in accordance with embodiments of the present disclosure.

FIG. 8 illustrates a schematic diagram of components of a charge circuit within a motor drive system in accordance with embodiments of the present disclosure.

FIG. 9 illustrates a schematic diagram of components of a charge circuit within a motor drive system in accordance with embodiments of the present disclosure.

FIG. 10 illustrates plot diagrams of waveforms within a motor drive system in accordance with embodiments of the present disclosure.

FIG. 11 illustrates a schematic diagram of components of a charge circuit within a motor drive system in accordance with embodiments of the present disclosure.

FIG. 12 illustrates a schematic diagram of components of a charge circuit within a motor drive system in accordance with embodiments of the present disclosure.

FIG. 13 illustrates a method for controlling operation of a motor drive system in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to encompass either an indirect connection or a direct connection. Thus, if a first device couples to, or is coupled to, a second device, that connection between the first device and the second device may be through a direct connection or through an indirect connection via other devices and connections.

Further, although the terms “first,” “second,” and so forth may be used herein to describe various elements, these elements should not be limited by these terms. Terms such as “first” and “second” may be used merely to distinguish one element from another. For example, a first element could be termed a second element, and, similarly, a second element could be termed a first element, without departing from the scope of the present disclosure. Further, the identification of a “first” element, does not necessarily require the presence of a “second” element. As used herein, the term “and/or” includes any and all combinations of one or more of the associated listed items.

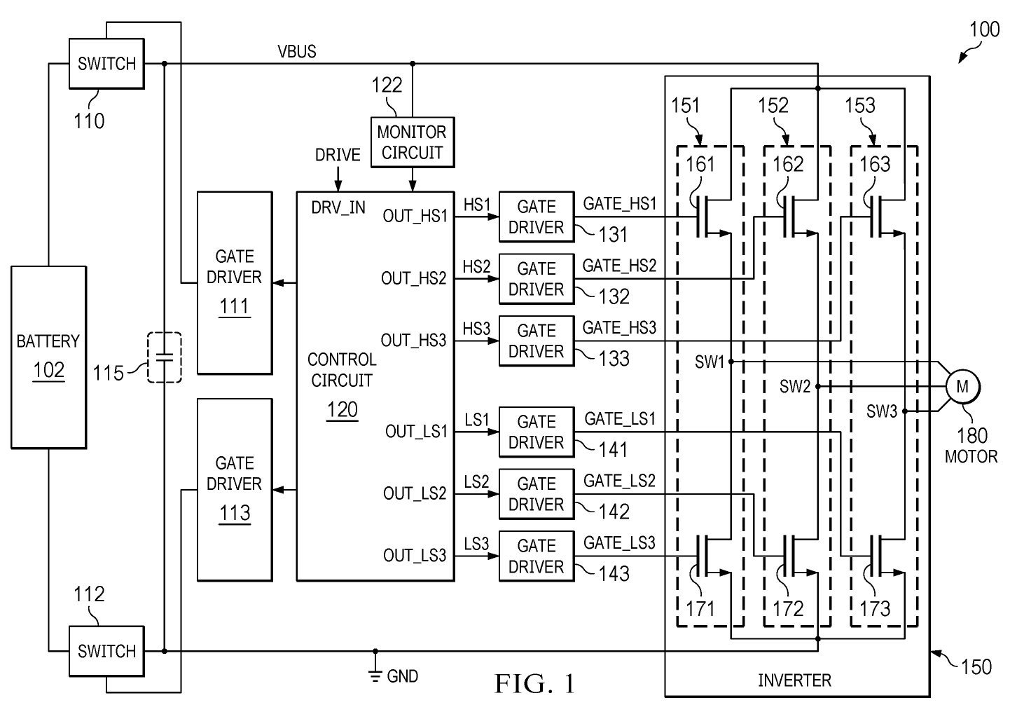

FIG. 1 illustrates a schematic diagram of motor drive system 100 in accordance with embodiments of the present disclosure. Motor drive system 100 may be implemented in any suitable fashion according to the operation described herein. In some embodiments, motor drive system 100 may include battery 102, switch 110, switch 112, DC link capacitor 115, gate driver 111, gate driver 113, control circuit 120, monitor circuit 122, gate drivers 131-133, gate drivers 141-143, inverter 150, and motor 180.

Motor drive system 100 may be powered by battery 102. Battery 102 may be a high-voltage battery that may be configured to provide power to inverter 150 and ultimately to motor 180 to generate the motive force for an electric vehicle for example. Battery 102 may be configured to operate at 400 V or 800 V for example. During operation of the electric vehicle, switch 110 and switch 112 may be operated in a closed state in order to couple battery 102 across the DC voltage bus VBUS and the system ground GND. For example, in embodiments where switch 110 and switch 112 are solid-state devices, such as transistors formed on respective silicon or silicon carbide substrates, control circuit 120 may drive each of switch 110 and switch 112 in a closed state (an on-state of the transistor) via gate driver 111 and gate driver 113 to couple battery 102 across the DC voltage bus VBUS and the system ground GND during operation of the electric vehicle.

DC link capacitor 115 may be coupled to the DC voltage bus VBUS. Specifically, DC link capacitor 115 may be coupled across the DC voltage bus VBUS and the system ground GND. DC link capacitor 115 may be a large energy storage capacitor that may smooth any transient ripples that would otherwise occur on VBUS, for example, due to the switching of inverter 150. In some embodiments, DC link capacitor 115 may have a large capacitance in the range of 200 µF, 500 µF, 1000 µF, 1500 µF, or more.

Motor 180 may in some embodiments be a three-phase electrical motor. For example, motor 180 may include three windings configured to be driven by the respective three phases of inverter 150 described below.

Inverter 150 may be coupled to the DC voltage bus VBUS. Specifically, inverter 150 may be coupled between the DC voltage bus VBUS and the system ground GND, and may thus draw power from the DC voltage bus VBUS to drive motor 180. In some embodiments, inverter 150 may include multiple phases that may each include a first switch and a second switch coupled in series between the DC voltage bus VBUS and system ground GND. For example, inverter 150 may include a first phase 151 coupled to a first winding of motor 180 at switching node SW1, a second phase 152 coupled to the second winding of motor 180 at switching node SW2, and a third phase 153 coupled to the third winding of motor 180 at switching node SW3. As shown in FIG. 1, first phase 151 may include high-side switch 161 coupled between VBUS and SW1, and low-side switch 171 coupled between SW1 and GND. Second phase 152 may include high-side switch 162 coupled between VBUS and SW2, and low-side switch 172 coupled between SW2 and GND. Further, third phase 153 may include high-side switch 163 coupled between VBUS and SW3, and low-side switch 173 coupled between SW3 and GND.

As depicted in FIG. 1, high-side switches 161-163 and low-side switches 171-173 may each be implemented in some embodiments as n-type metal-oxide semiconductor field-effect transistors (n-type MOSFETs or NMOS transistors). In some embodiments, high-side switches 161-163 and low-side switches 171-173 may be NMOS transistors formed with a silicon carbide (SiC) semiconductor material. In other embodiments, high-side switches 161-163 and low-side switches 171-173 may be formed with other semiconductor materials, such as silicon (Si) or any other semiconductor material suitable for the high-power and high-voltage operation of inverter 150. Although FIG. 1 illustrates an embodiment where high-side switches 161-163 and low-side switches 171-173 are implemented as NMOS transistors, high-side switches 161-163 and low-side switches 171-173 may also be implemented with any other suitable transistor type. For example, high-side switches 161-163 and low-side switches 171-173 may also be implemented with insulated gate bipolar transistors (IGBTs) formed for example with silicon (Si) or silicon carbide (SiC), or any other semiconductor material suitable for the high-power and high-voltage operation of inverter 150. In some embodiments, high-side switches 161-163 and low-side switches 171-173 may each be formed on their own semiconductor die and separately packaged as discrete transistors. In other embodiments, high-side switches 161-163 and low-side switches 171-173 may be formed either on the same semiconductor die or on separate semiconductor dies, and co-packaged together in a single-die or multi-die power module package.

Control circuit 120 may be implemented in any suitable fashion according to the operation described herein. Control circuit 120 may be implemented with software, digital circuitry, analog circuitry, or any suitable combination thereof. For example, in some embodiments, control circuit 120 may be implemented with a microcontroller unit (MCU) including a digital core, software, memory, and any suitable analog peripherals for interfacing with other components of motor drive system 100.

As shown in FIG. 1, control circuit 120 may be coupled to control inverter 150. For example, control circuit may include a plurality of outputs (OUT_HS1, OUT_HS2, OUT_HS3, OUT_LS1, OUT_LS2, and OUT_LS3) configured to control the switching of inverter 150, which may in turn be coupled to drive motor 180. For example, OUT_HS1 may be configured to drive high-side switch 161 via gate driver 131, and OUT_LS1 may be configured to drive low-side switch 171 via gate driver 141. Similarly, OUT_HS2 may be configured to drive high-side switch 162 via gate driver 132, and OUT_LS2 may be configured to drive low-side switch 172 via gate driver 142. Further, OUT_HS3 may be configured to drive high-side switch 163 via gate driver 133, and OUT_LS3 may be configured to drive low-side switch 173 via gate driver 143.

Gate drivers 131-133 may be high-side gate drivers and may translate the high-side control signals HS1, HS2, and HS3 from control circuit 120 into high-side gate drive signals GATE_HS1, GATE_HS2, and GATE_HS3 suitable to directly drive the respective gates of the high-side switches 161-163. For example, gate drivers 131-133 may include level-shifting circuitry and buffer circuits suitable to directly drive the gates of high-side switches 161-163 to turn those switches on and off at high speeds. Gate drivers 141-143 may be low-side gate drivers and may translate the low-side control signals LS1, LS2, and LS3 from control circuit 120 into low-side gate drive signals GATE_LS1, GATE_LS2, and GATE_LS3 suitable to directly drive the respective gates of the low-side switches 171-173. For example, gate drivers 141-143 may include level-shifting circuitry and buffer circuits suitable to directly drive the gates of low-side switches 171-173 to turn those switches on and off at high speeds. In some embodiments, gate drivers 131-133 and gate drivers 141-143 may be implemented as separate circuits from control circuit 120 as shown in FIG. 1. In other embodiments, gate drivers 131-133 and gate drivers 141-143 may be directly incorporated within control circuit 120. Because gate drivers 131-133 and gate drivers 141-143 translate the control signals from control circuit 120 to gate drive signals applied to the gates of high-side switches 161-163 and low-side switches 171-173, those high-side switches 161-163 and low-side switches 171-173 may be considered, for the purposes of the present disclosure, to be driven by either of control circuit 120 or by the respective gate drivers 131-133 and gate drivers 141-143.

Control circuit 120 may include a drive input DRV_IN. During operation of the electric vehicle in which motor drive system 100 is implemented, control circuit 120 may receive a drive signal DRIVE that may instruct control circuit 120 how to drive inverter 150 (and thus ultimately motor 180) to provide the required motive force for the electric vehicle. In response to certain conditions, motor drive system 100 may be powered down. For example, when the electric vehicle is turned off, or in the event of a detected crash, control circuit 120 may drive each of switch 110 (via gate driver 111) and switch 112 (via gate driver 113) in an open state to isolate the DC voltage bus VBUS and system ground GND from battery 102.

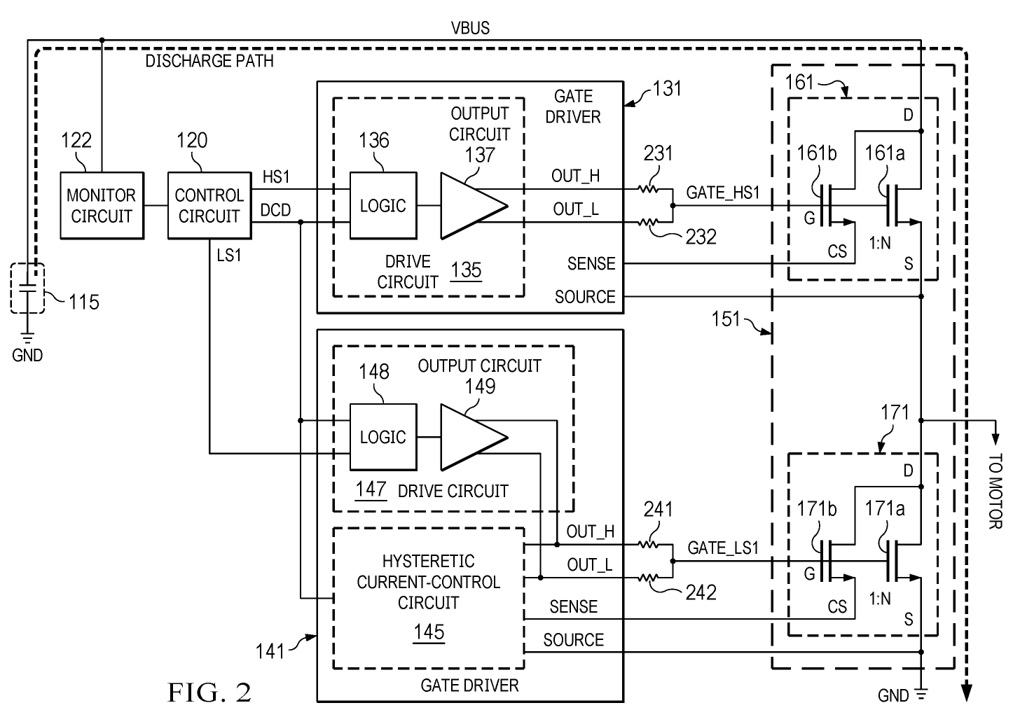

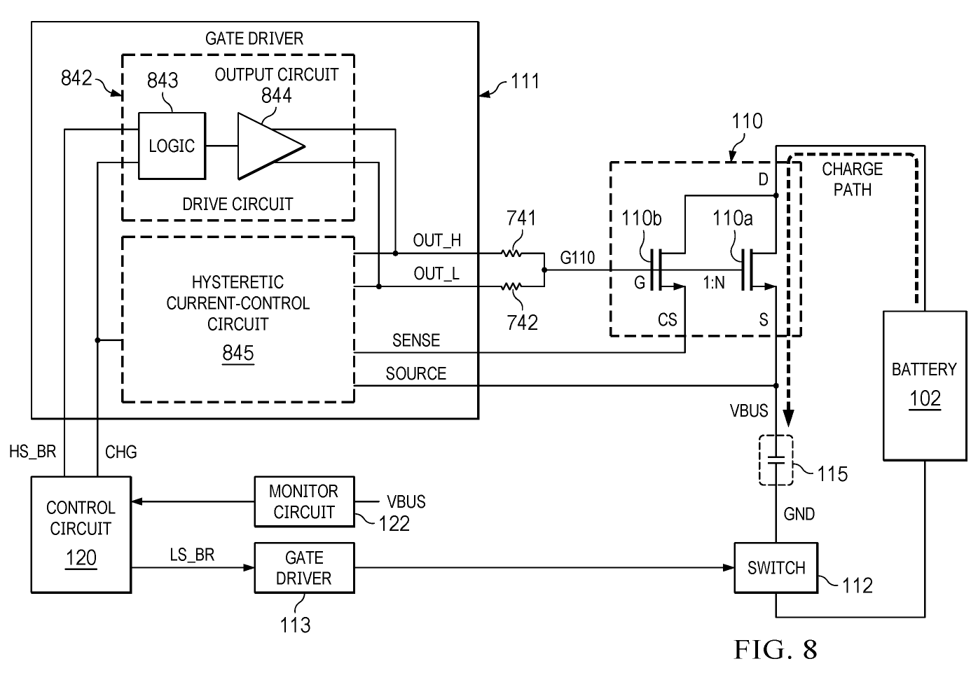

As described in further detail below with reference to FIGS. 2-7, control circuit 120 may initiate a controlled discharge of DC link capacitor 115 when the electric vehicle is turned off. Such discharge may improve safety by removing the high-voltage present on VBUS when the electric vehicle is turned off. As also described in further detail below with reference to FIGS. 8-13, control circuit 120 may initiate a controlled pre-charge of DC link capacitor 115 to re-charge DC link capacitor 115 prior to the electric vehicle resuming operation. Such a controlled pre-charge of DC link capacitor 115 may prevent large, and potentially damaging, in-rush currents when switches 110 and 112 are turned fully on in order to couple battery 102 across the DC voltage bus VBUS and the system ground GND.

FIG. 2 illustrates a schematic diagram of components of a discharge circuit within a motor drive system in accordance with embodiments of the present disclosure. Specifically, FIG. 2 illustrates further details of certain components within motor drive system 100 that form a discharge circuit configured to discharge DC link capacitor 115 in response to a discharge command DCD.

The switches of at least one phase of inverter 150 may be utilized to discharge DC link capacitor 115. For the purposes of illustration, first phase 151 of inverter 150 is shown in FIG. 2 and described below with respect to the controlled discharge of DC link capacitor 115. However, in various embodiments, one or more of any of first phase 151, second phase 152, and third phase 153 may be driven in parallel, or in sequence to each other, to perform a controlled discharge of DC link capacitor 115 in a similar manner as described below.

In some embodiments, high-side switch 161 may include power-FET 161aand sense-FET 161b. Power-FET 161a may be configured at a size sufficient to handle the high voltage and high currents for driving motor 180. Sense-FET 161b may be sized at a ratio of 1:N relative to power-FET 161a, where N equals, for example, 10, 100, 1000, 10000, or more. In some embodiments, sense-FET 161b may be formed by a one or more MOSFET cells monolithically integrated and/or laid out together with a plurality of MOSFET cells forming power-FET 161a. As shown in FIG. 2, the gate of sense-FET 161b may be coupled to the gate of power-FET 161a at gate input G, and the drain of sense-FET 161b may be coupled to the drain of power-FET 161a at drain node D. Sense-FET 161b may thus be configured to produce a sense current, corresponding to the current through power-FET 161a, at the current-sense node CS coupled to the source of sense-FET 161b.

Further, low-side switch 171 may include power-FET 171a and sense-FET 171b. Power-FET 171a may be configured at a size sufficient to handle the high voltage and high currents for driving motor 180. Sense-FET 171b may be sized at a ratio of 1:N relative to power-FET 171a, where N equals, for example, 10, 100, 1000, 10000, or more. In some embodiments, sense-FET 171b may be formed by one or more MOSFET cells monolithically integrated and/or laid out together with a plurality of MOSFET cells forming power-FET 171a. As shown in FIG. 2, the gate of sense-FET 171b may be coupled to the gate of power-FET 171a at gate input G, and the drain of sense-FET 171b may be coupled to the drain of power-FET 171a at drain node D. Sense-FET 171b may thus be configured to produce a sense current, corresponding to the current through power-FET 171a, at the current-sense node CS coupled to the source of sense-FET 171b. As described in further detail below, the sense currents provided by one or both of sense-FET 161b or sense-FET 171bmay be utilized to sense, and thereby regulate, a discharge current through the switches of the first phase 151 of inverter 150.

The discharge circuit within motor drive system 100 may include a first gate driver (such as gate driver 131) configured to drive a first switch (such as high-side switch 161) of the first phase 151 of inverter 150 in an on-state in response to a discharge command DCD. For example, as shown in FIG. 2, gate driver 131 may include a drive circuit 135 including logic circuit 136 and output circuit 137. Logic circuit 136 may be configured to receive a high-side control signal HS1 and a discharge command DCD from control circuit 120. Logic circuit 136 may control output circuit 137, which may include level shifters and/or buffers required to drive the gate of high-side switch 161. As shown in FIG. 2, output circuit 137 may include a high output OUT_H which may drive the gate of high-side switch 161 high via resistor 231, and may also include a low output OUT_L that may drive the gate of high-side switch 161 low via resistor 232. During normal operation of the electric vehicle, logic circuit 136 may control output circuit 137 to drive high-side transistor on and off based on the high-side control signal HS1. However, in response to a discharge command DCD, logic circuit 136 may control output circuit 137 to drive the gate of high-side switch 161 high to force high-side switch 161 in an on-state.

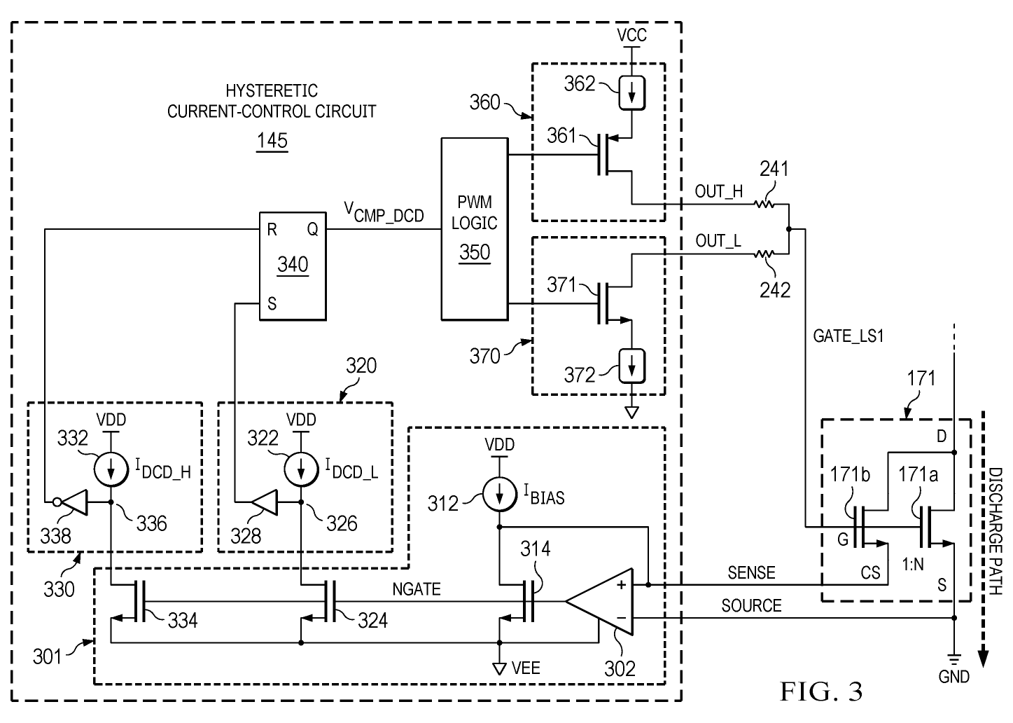

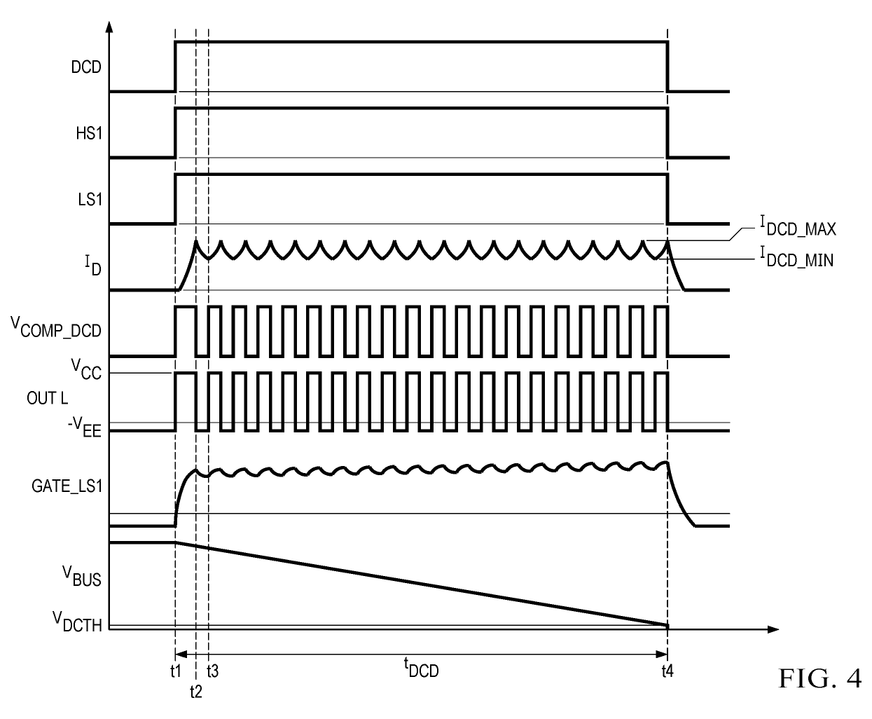

The discharge circuit within motor drive system 100 may also include a second gate driver (such as gate driver 141) configured to drive a second switch (such as low-side switch 171) of the first phase 151 of inverter 150. As shown in FIG. 2, gate driver 141 may include a drive circuit 147 and hysteretic current-control circuit 145. Drive circuit 147 may include logic circuit 148 and output circuit 149. Logic circuit 148 may be configured to receive a low-side control signal LS1 and a discharge command DCD from control circuit 120. Logic circuit 148 may control output circuit 149, which may include level shifters and/or buffers required to drive the gate of low-side switch 171. As shown in FIG. 2, output circuit 149 may include a high output OUT_H which may drive the gate of low-side switch 171 high via resistor 241, and may also include a low output OUT_L that may drive the gate of low-side switch 171 low via resistor 242. During normal operation of the electric vehicle, logic circuit 148 may control output circuit 149 to drive low-side switch 171 on and off based on the low-side control signal LS1. However, in response to a discharge command DCD, logic circuit 148 may disable output circuit 149, thereby allowing hysteretic current-control circuit 145 to take over control of the gate of low-side switch 171. And as described in further detail below with reference to FIGS. 3 and 4, hysteretic current-control circuit 145 may be configured to, in response to the discharge command DCD, regulate a discharge current through a second switch (such as low-side switch 171) of the first phase 151 of inverter 150 based on a minimum-discharge-current threshold and a maximum-discharge-current threshold.

FIG. 3 illustrates a schematic diagram of components of a discharge circuit within a motor drive system in accordance with embodiments of the present disclosure. Specifically, FIG. 3 illustrates further details of hysteretic current-control circuit 145 and its operation with low-side switch 171.

Hysteretic current-control circuit 145 may be implemented in any suitable fashion according to the operation described herein. As shown in FIG. 3, hysteretic current-control circuit 145 may include current mirror circuit 301, first comparator 320, second comparator 330, latch 340, PWM logic 350, current-starved pull-up circuit 360, and current-starved pull-down circuit 370.

Current mirror circuit 301 may be configured to mirror the sense current from the sense-FET of the second switch (such as the sense current from the sense-FET 171bof low-side switch 171). In some embodiments, current mirror circuit 301 may include amplifier 302, current source 312, and transistors 314, 324, and 334. Amplifier 302 may have a first input (for example, the negative “-” input) coupled to the source of power-FET 171a, and a second input (for example, the positive “+” input) coupled to the source of sense-FET 171b. Amplifier 302 may also have an output coupled to drive the gate of transistor 314 at node NGATE. As shown in FIG. 3, transistor 314 may have a gate coupled to be driven by the output of amplifier 302, a source coupled to voltage rail VEE, and a drain coupled to the second input of amplifier 302 and the source of sense-FET 171b. Accordingly, amplifier 302 may drive the gate of transistor 314 at the gate voltage required for transistor 314 to sink the sense current from sense-FET 171b. The feedback loop formed by transistor 314 back to the positive input of amplifier 302 may ensure that the voltage at the positive input of amplifier 302 (coupled to the source of sense-FET 171b) approximately equals the voltage at the negative input (coupled to the source of power-FET 171a), thereby ensuring a close match between the sense current through sense-FET 171band the discharge current through power-FET 171a at the designed 1:N ratio. In some embodiments, voltage rail VEE may be provided at a negative voltage relative to the source of power-FET 171a in order to provide sufficient voltage headroom for amplifier 302 to operate. Further, in some embodiments, current source 312 may provide a bias current I_{BIAS} to the node that couples together the drain of transistor 314 and the positive input of amplifier 302. The bias current I_{BIAS} may keep the feedback loop formed by amplifier 302 and transistor 314 biased, for example, during times of no sense current from sense-FET 171b.

As shown in FIG. 3, transistors 324 and 334 may each have a gate coupled to the same node NGATE as the gate of transistor 314, and may each have a source coupled to the same voltage rail VEE as transistor 314. Further, transistors 324 and 334 may be configured to match transistor 314. For example, in embodiments where transistor 314 is an NMOS transistor, transistors 324 and 334 may be formed by matching NMOS transistors. Accordingly, transistors 324 and 334 may each mirror the sense current from sense-FET 171b.

First comparator 320 may be configured to compare a first mirrored sense-FET current (produced at the drain of transistor 324) against a first current threshold I_{DCD_L} corresponding to the minimum-discharge-current threshold, which is illustrated in FIG. 4 as I_{DCD_MIN}. For example, first comparator 320 may include current source 322 and buffer 328. Current source 322 may be coupled between voltage rail VDD and node 326, which may in turn be coupled to the drain of transistor 324. First comparator 320 may thus compare the first mirrored sense-FET current produced by transistor 324 against the first current threshold I_{DCD_L} produced by current source 322. The first current threshold I_{DCD_L} may correspond to the minimum-discharge-current threshold I_{DCD_MIN} for the discharge current through low-side switch 171. For example, the first current threshold I_{DCD_L} may be scaled relative to the minimum-discharge-current threshold at the same 1:N ratio as the scaling for the relative sizes of sense-FET 171b and power-FET 171a(or any other ratio further accounting for any scaling between transistors 314 and 324). In some embodiments, the first current threshold I_{DCD_L} may be further adjusted to account for any offsets to the first mirrored sense-FET current caused by the bias current I_{BIAS} in current mirror circuit 301. When the discharge current through low-side switch 171 is greater than the minimum-discharge-current threshold I_{DCD_MIN,} the first mirrored sense-FET current produced by transistor 324 may in turn be greater than the first current threshold I_{DCD_L}, and thus the voltage at node 326 may go low to thereby cause buffer 328 to output a logic-low signal. Conversely, when the discharge current through low-side switch 171 is less than the minimum-discharge-current threshold I_{DCD_MIN,} the first mirrored sense-FET current produced by transistor 324 may in turn be less than the first current threshold I_{DCD_L}, and thus the voltage at node 326 may go high to thereby cause buffer 328 to output a logic-high signal.

Second comparator 330 may be configured to compare a second mirrored sense-FET current (produced at the drain of transistor 334) against a second current threshold I_{DCD_H} corresponding to the maximum-discharge-current threshold, which is illustrated in FIG. 4 as I_{DCD_MAX}. For example, second comparator 330 may include current source 332 and inverter 338. Current source 332 may be coupled between voltage rail VDD and node 336, which may in turn be coupled to the drain of transistor 334. Second comparator 330 may thus compare the second mirrored sense-FET current produced by transistor 334 against the second current threshold I_{DCD_H} produced by current source 332. The second current threshold I_{DCD_H} may correspond to the maximum-discharge-current threshold I_{DCD_MAX} for the discharge current through low-side switch 171. For example, the second current threshold I_{DCD_H} may be scaled relative to the maximum-discharge-current threshold at the same 1:N ratio as the scaling for the relative sizes of sense-FET 171b and power-FET 171a (or any other ratio further accounting for any scaling between transistors 314 and 334). In some embodiments, the second current threshold I_{DCD_H} may be further adjusted to account for any offsets to the second mirrored sense-FET current caused by the bias current I_{BIAS} in current mirror circuit 301. When the discharge current through low-side switch 171 is greater than the maximum-discharge-current threshold I_{DCD_MAX,} the second mirrored sense-FET current produced by transistor 334 may in turn be greater than the second current threshold I_{DCD_H}, and thus the voltage at node 336 may go low to thereby cause inverter 338 to output a logic-high signal. Conversely, when the discharge current through low-side switch 171 is less than the maximum-discharge-current threshold I_{DCD_MAX,} the second mirrored sense-FET current produced by transistor 334 may in turn be less than the second current threshold I_{DCD_H}, and thus the voltage at node 336 may go high to thereby cause inverter 338 to output a logic-low signal.

As shown in FIG. 3, latch 340 may include a set input S coupled to the output of first comparator 320, a reset input R coupled to the output of second comparator 330, and an output configured to provide a discharge current comparison signal V_{CMP_DCD}. The discharge current comparison signal V_{CMP_DCD} may be provided to PWM logic 350, which in turn may drive current-starved pull-up circuit 360 and current-starved pull-down circuit 370.

Current-starved pull-up circuit 360 may include transistor 361 and current-limiter 362. In some embodiments, transistor 361 may be a PMOS transistor. Current-limiter 362 may be coupled between supply rail VCC and transistor 361. Transistor 361 may have a source coupled to current-limiter 362 and a drain coupled to the high output OUT_H of gate driver 141. In some embodiments, current-limiter 362 may be implemented by a current source, a resistor, or any other circuit element suitable to limit the pull-up current provided by transistor 361 to the gate of low-side switch 171 when current-starved pull-up circuit 360 is enabled by PWM logic 350.

Current-starved pull-down circuit 370 may include transistor 371 and current-limiter 372. In some embodiments, transistor 371 may be an NMOS transistor. Current-limiter 372 may be coupled between VEE and transistor 371. Transistor 371 may have a source coupled to current-limiter 372 and a drain coupled to the low output OUT_L of gate driver 141. In some embodiments, current-limiter 372 may be implemented by a current source, a resistor, or any other circuit element suitable to limit the pull-down current provided by transistor 371 to the gate of low-side switch 171 when current-starved pull-down circuit 370 is enabled by PWM logic 350.

Current-starved pull-up circuit 360 may be configured to increase the gate volage of the second switch (the gate voltage of low-side switch 171 for example) in response to the discharge current crossing below the minimum-discharge-current threshold I_{DCD_MIN}. For example, as described above, when the discharge current through low-side switch 171 is below the minimum-discharge-current threshold I_{DCD_MIN}, first comparator 320 may set latch 340, causing V_{CMP_DCD} to go high. When V_{CMP_DCD} goes high, PWM logic 350 may disable current-starved pull-down circuit 370, and may enable current-starved pull-up circuit 360. In turn, current-starved pull-up circuit 360 may charge the gate capacitance of low-side switch 171 to thereby increase the gate voltage of low-side switch 171. The discharge current may in turn increase with the increased gate voltage.

Current-starved pull-down circuit 370 may be configured to decrease the gate volage of the second switch (the gate voltage of low-side switch 171 for example) in response to the discharge current crossing above the maximum-discharge-current threshold I_{DCD_MAX}. For example, as described above, when the discharge current through low-side switch 171 is above maximum-discharge-current threshold I_{DCD_MAX}, second comparator 330 may reset latch 340, causing V_{CMP_DCD} to go low. When V_{CMP_DCD} goes low, PWM logic 350 may disable current-starved pull-up circuit 360, and may enable current-starved pull-down circuit 370. In turn, current-starved pull-down circuit 370 may discharge the gate capacitance of low-side switch 171 to thereby reduce the gate voltage of low-side switch 171. The discharge current may in turn decrease with the decreased gate voltage.

FIG. 4 illustrates plot diagrams of waveforms within motor drive system 100 in accordance with embodiments of the present disclosure. Specifically, FIG. 4 illustrates waveforms showing the hysteretic control of the discharge current provided by hysteretic current-control circuit 145 described above with reference to FIGS. 2 and FIG. 3.

As shown in FIG. 4, high-side control signal HS1 and low-side control signal LS1 may both be at logic-low levels before time t1 to force gate driver 131 and gate driver 141 to drive high-side switch 161 and low-side switch 171 of the first phase 151 of inverter 150 in respective off-states. At time t1, control circuit 120 may assert a discharge command DCD to initiate a controlled discharge of DC link capacitor 115 coupled to DC voltage bus VBUS. As described above with reference to FIG. 2, gate driver 131 may drive high-side switch 161 in an on-state in response to the discharge command DCD. Further, the hysteretic current-control circuit 145 within gate driver 141 may drive the gate of low-side switch 171 to regulate the discharge current that may flow from DC link capacitor 115, through high-side switch 161, through low-side switch 171, and to system ground GND.

With the discharge current at time t1 below the minimum-discharge-current threshold I_{DCD_MIN}, first comparator 320 may set latch 340, causing V_{CMP_DCD} to go high and thereby enabling current-starved pull-up circuit 360 to slowly charge the gate capacitance of low-side switch 171 to increase the gate voltage of low-side switch 171. As shown in FIG. 4, the discharge current I_{D} that flows from DC link capacitor 115, through high-side switch 161, through low-side switch 171, and to system ground GND will increase as the gate voltage of low-side switch 171 increases.

When the discharge current I_{D} reaches and crosses just above the maximum-discharge-current threshold I_{DCD_MAX} at time t2, second comparator 330 may reset latch 340, causing V_{CMP_DCD} to go low. In response, PWM logic 350 may disable current-starved pull-up circuit 360 and enable current-starved pull-down circuit 370. Accordingly, current-starved pull-down circuit 370 may discharge the gate capacitance of low-side switch 171 to thereby reduce the gate voltage of low-side switch 171. As shown in FIG. 4, the discharge current I_{D} that flows from DC link capacitor 115, through high-side switch 161, through low-side switch 171, and to system ground GND will decrease as the gate voltage of the low-side switch 171 decreases. Subsequently, when the discharge current I_{D} reaches and crosses just below the minimum-discharge-current threshold I_{DCD_MIN} at time t3, first comparator 320 may again set latch 340, causing V_{CMP_DCD} to go high. In response, PWM logic 350 may disable current-starved pull-down circuit 370 and enable current-starved pull-up circuit 360. Accordingly, current-starved pull-up circuit 360 may charge the gate capacitance of low-side switch 171 to thereby increase the gate voltage of low-side switch 171.

As shown in FIG. 4, the DC bus voltage VBUS will decrease as the discharge current I_{D} cyclically varies between the minimum-discharge-current threshold I_{DCD_MIN} and the maximum-discharge-current threshold I_{DCD_MAX} and thereby discharges DC link capacitor 115. The discharge period t_{DCD} may last from time t1 to the time t4 when the DC bus voltage VBUS reaches the discharge threshold V_{DCTH}. The discharge threshold V_{DCTH} may be 60 V for example, or any other voltage level suitable to ensure user safety. In some embodiments, a first gate driver (gate driver 131 for example) and a second gate driver (gate driver 141 for example) may be configured to drive a first switch (high-side switch 161 for example) and a second switch (low-side switch 171 for example) of the first phase 151 of inverter 150 in respective off states in response to a voltage of DC link capacitor 115 crossing below the discharge threshold V_{DCTH}. The discharge path may thus be cut off after completion of the discharge to the discharge threshold V_{DCTH}.

As shown in FIG. 2, the discharge circuit within motor drive system 100 may include monitor circuit 122. Monitor circuit 122 may be implemented in any suitable fashion according to the functionality described herein. In some embodiments, monitor circuit 122 may be implemented as a separate block from control circuit 120. In other embodiments, monitor circuit 122 may be incorporated within control circuit 120. Monitor circuit 122 may provide multiple functions. In some embodiments, monitor circuit 122 may monitor VBUS, and thereby the voltage of the DC link capacitor 115 coupled to VBUS. When monitor circuit 122 detects that VBUS has been discharged down to the discharge threshold V_{DCTH}, monitor circuit 122 may instruct control circuit 120 to conclude the discharge time. In turn, control circuit 120 may control gate driver 131 to drive high-side switch 161 in an off state, and may control gate driver 141 to drive low-side switch 171 in an off state.

Monitor circuit 122 may also be configured to record a discharge time required for the discharge current to discharge the DC link capacitor 115 to the discharge threshold V_{DCTH} for each of a plurality of discharge cycles. Monitor circuit 122 may then utilize this information to monitor the health of DC link capacitor 115. In some embodiments, monitor circuit 122 may be configured to estimate a capacitance of the DC link capacitor 115 based on the discharge current and a recorded discharge time. For example, the capacitance of DC link capacitor 115 may be expressed as C₁₁₅ = I_{D} x (dt/dV), where C₁₁₅ is the capacitance value of DC link capacitor 115, I_{D} is the average discharge current, dt is the recorded discharge time, and dV is the voltage delta from the normal operating voltage (400 V for example) down to the discharge threshold V_{DCTH} (60 V for example). The average discharge current I_{D} may be represented by the average of known quantities for the minimum-discharge-current threshold I_{DCD_MIN} and the maximum-discharge-current threshold I_{DCD_MAX}. Further, dV may simply be the difference between the known quantities for the normal operating voltage and the discharge threshold V_{DCTH}. Accordingly, the capacitance of DC link capacitor 115 may be determined based on the recorded discharge time. A drop in the capacitance value of DC link capacitor 115 over time may indicate that DC link capacitor 115 may soon fail. Accordingly, monitor circuit 122 may also be configured to produce an alert in response to a change in an estimated capacitance of the DC link capacitor 115. Such an alert may prompt the user of the electric vehicle (or the entity responsible for maintenance of the electric vehicle) to replace DC link capacitor 115 before failure.

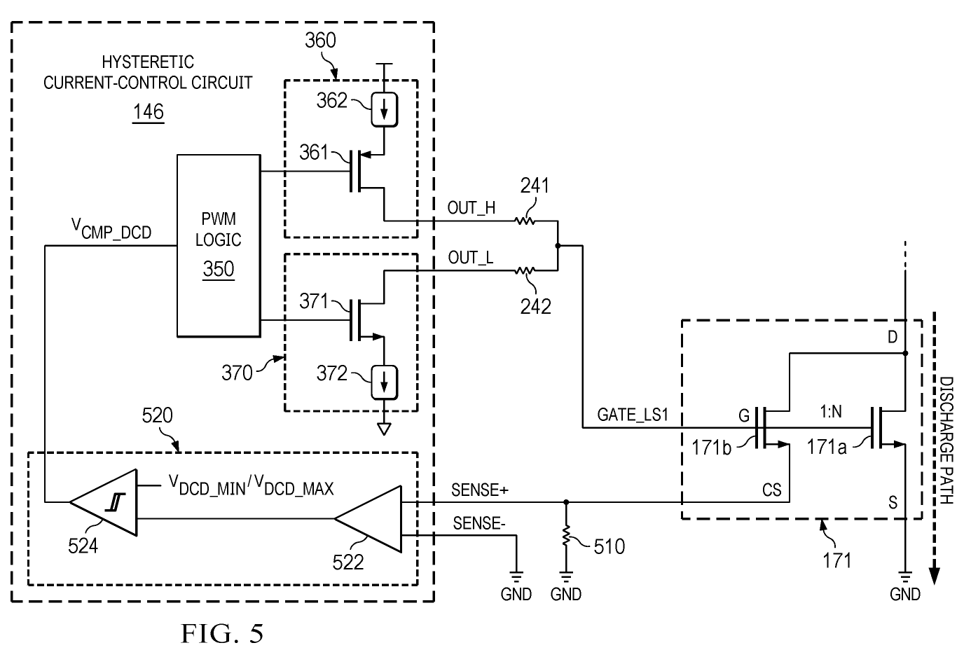

FIG. 5 illustrates a schematic diagram of components of a discharge circuit within a motor drive system in accordance with embodiments of the present disclosure. Specifically, FIG. 5 illustrates details of hysteretic current-control circuit 146, which may serve as an alternative implementation of hysteretic current-control circuit 145 described above with reference to FIGS. 2-4.

As shown in FIG. 5, sense resistor 510 may be coupled to produce a sense voltage based on a sense current from a sense-FET of a second switch (for example, based on a sense current from sense-FET 171b of low-side switch 171). For example, sense resistor 510 may be coupled between the source of sense-FET 171b and system ground GND, and may thus produce a sense voltage based on the sense current from sense-FET 171b. The sense voltage may thus correspond to the discharge current through low-side switch 171. And as described below, hysteretic current-control circuit 146 may utilize the sense voltage to hysteretically regulate the discharge current through low-side switch 171.

Hysteretic current-control circuit 146 may include a hysteretic voltage comparator 520, PWM logic 350, current-starved pull-up circuit 360, and current-starved pull-down circuit 370. Hysteretic voltage comparator 520 may be configured to compare the sense voltage produced by sense resistor 510 against a first voltage threshold V_{DCD_MIN} corresponding to the minimum-discharge-current threshold I_{DCD_MIN}, and against a second voltage threshold V_{DCD_MAX} corresponding to the maximum-discharge-current threshold I_{DCD_MAX}.

In some embodiments, hysteretic voltage comparator 520 may include sense amplifier 522 and hysteretic comparator 524. Sense amplifier 522 may amplify and/or buffer the sense voltage produced across sense resistor 510, and may provide an output to hysteretic comparator 524. Hysteretic comparator 524 may have a built-in hysteresis, and may thus compare the output of sense amplifier 522 against both of the first voltage threshold V_{DCD_MIN} the second voltage threshold V_{DCD_MAX} to produce a discharge current comparison signal V_{CMP_DCD}.

The discharge current comparison signal V_{CMP_DCD} may drive PWM logic 350, and thus current-starved pull-up circuit 360 and current-starved pull-down circuit 370, in a similar manner as described above for hysteretic current-control circuit 145 with reference to FIGS. 3-4. For example, when the discharge current I_{D} reaches and crosses just above the maximum-discharge-current threshold I_{DCD_MAX}, hysteretic voltage comparator 520 may assert V_{CMP_DCD} at a logic low level. In response, PWM logic 350 may disable current-starved pull-up circuit 360 and enable current-starved pull-down circuit 370. Accordingly, current-starved pull-down circuit 370 may discharge the gate capacitance of low-side switch 171 to thereby reduce the gate voltage of low-side switch 171. As shown in FIG. 4, the discharge current I_{D} that flows from DC link capacitor 115, through high-side switch 161, through low-side switch 171, and to system ground GND will decrease as the gate voltage of the low-side switch 171 decreases. Subsequently, when the discharge current I_{D} reaches and crosses just below the minimum-discharge-current threshold I_{DCD_MIN}, hysteretic voltage comparator 520 may assert V_{CMP_DCD} at a logic high level. In response, PWM logic 350 may disable current-starved pull-down circuit 370 and enable current-starved pull-up circuit 360. Thus, current-starved pull-up circuit 360 may charge the gate capacitance of low-side switch 171 to thereby increase the gate voltage of low-side switch 171. Accordingly, hysteretic current-control circuit 146 may hysteretically regulate the discharge current between the minimum-discharge-current threshold I_{DCD_MIN} and the maximum-discharge-current threshold I_{DCD_MAX} to thereby discharge DC link capacitor 115.

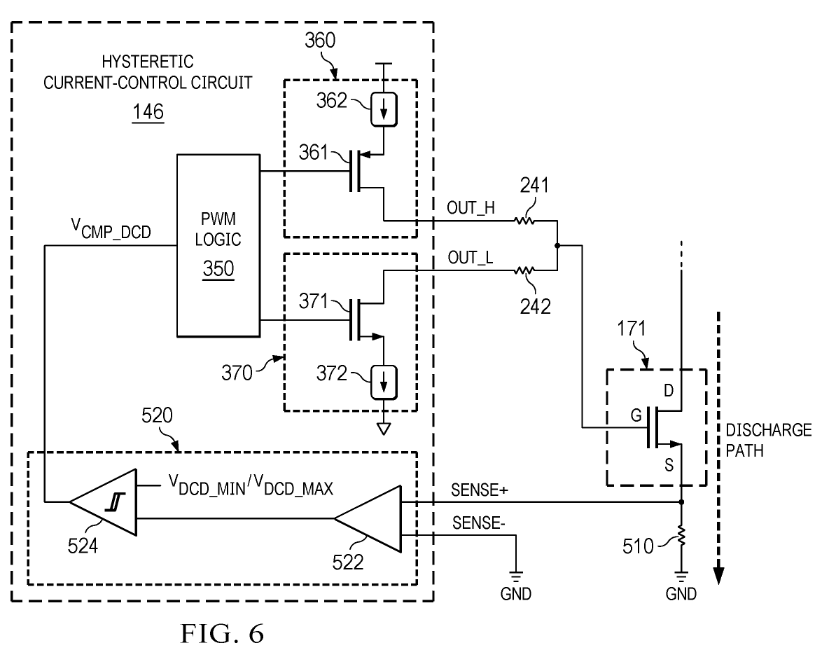

FIG. 6 illustrates a schematic diagram of components of a discharge circuit within a motor drive system in accordance with embodiments of the present disclosure. Specifically, FIG. 6 illustrates an alternative arrangement for sense resistor 510 and hysteretic current-control circuit 146 relative to the arrangement illustrated in FIG. 5.

As shown in FIG. 6, some embodiments of the second switch (for example low-side switch 171) may include a power-FET alone, instead of both a sense-FET integrated with a power-FET. For such embodiments, sense resistor 510 may be coupled in series with the second switch (for example, low side switch 171) to produce a sense voltage proportional to the discharge current. When placed directly in the discharge path as shown in FIG. 6, sense resistor 510 may be set to a low resistance value to reduce resistive loss that may otherwise occur when low-side switch 171 is turned on and off during normal operation of the electric vehicle.

In a similar manner as described above with reference to FIG. 5, hysteretic voltage comparator 520 may compare the sense voltage produced by sense resistor 510 against a first voltage threshold V_{DCD_MIN} corresponding to the minimum-discharge-current threshold I_{DCD_MIN}, and against a second voltage threshold V_{DCD_MAX} corresponding to the maximum-discharge-current threshold I_{DCD_MAX}. Accordingly, hysteretic current-control circuit 146 may hysteretically regulate the discharge current between the minimum-discharge-current threshold I_{DCD_MIN} and the maximum-discharge-current threshold I_{DCD_MAX} to thereby discharge DC link capacitor 115.

Various embodiments described above with reference to FIGS. 2-6 refer to high-side switch 161 as a first switch, gate driver 131 as a first gate driver, low-side switch 171 as a second switch, and gate driver 141 as the second gate driver. The designations of “first” or “second” for the above described embodiments is merely exemplary. For example, in some embodiments, gate driver 141 may serve as the first gate driver while gate driver 131 serves as the second gate driver. In a corresponding manner, low-side switch 171 may serve as the first switch while high-side switch 161 serves as the second switch. For such embodiments, hysteretic current-control circuit 145 (shown in FIGS. 2 and 3) may be implemented within gate driver 131 instead of gate driver 141 to regulate the discharge current through high-side switch 161 based on the sense current from sense-FET 161b of high-side switch 161. Alternatively, hysteretic current-control circuit 146 (shown in FIGS. 5 and 6) may be implemented within gate driver 131 instead of gate driver 141 to regulate the discharge current through high-side switch 161. With the discharge current being regulated based on the current through high-side switch 161, gate driver 141 may simply drive low-side switch 171 in a fully-on state.

Further, although the above described embodiments refer to regulating the discharge current through first phase 151 of inverter 150, gate drivers 131-133 and gate drivers 141-143 may be configured to regulate a discharge current through any one or more of the first phase 151, second phase 152, and third phase 153 of inverter 150 in the same manner as described above for first phase 151. In some embodiments, a discharge current through each of multiple phases may be regulated to provide parallel discharge paths. Accordingly, any strain placed on the high-side and/or low-side switches due to the total discharge current may be spread amongst multiple lower-current discharge paths. Further, in some embodiments, different phases of inverter 150 may be sequentially operated to discharge DC link capacitor 115. For example, first phase 151 may be driven to discharge DC link capacitor 115 for a first portion of the discharge period while second phase 152 and/or third phase 153 are driven to discharge DC link capacitor 115 for one or more later portions of the discharge period. Such sequential operation of the different phases may reduce the thermal strain over time on any one switch used to discharge the DC link capacitor 115.

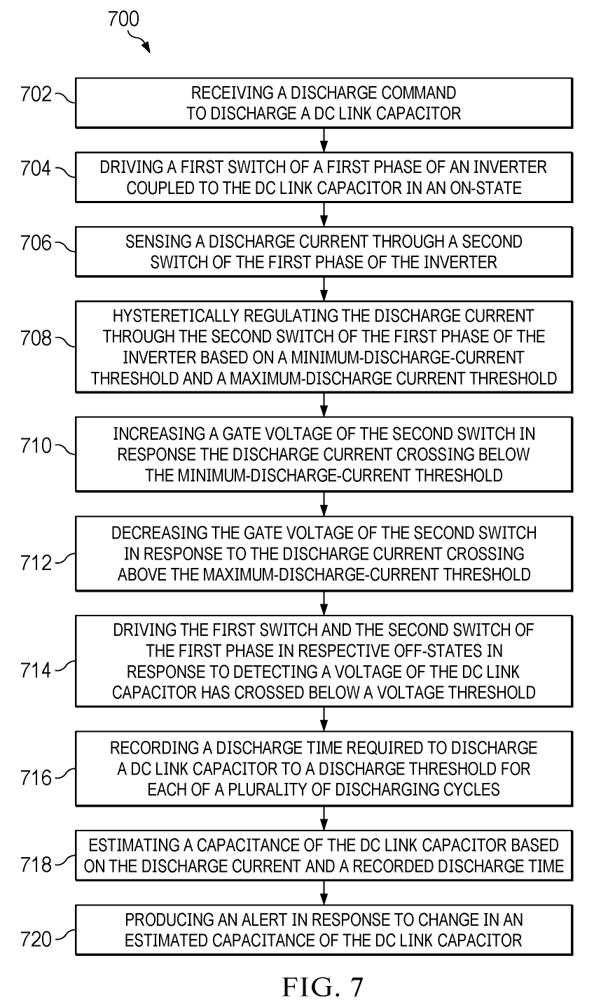

FIG. 7 illustrates a method for controlling operation of a motor drive system in accordance with embodiments of the present disclosure. Method 700 may be performed by any suitable mechanism, such as control circuit 120 alone or in combination with other elements of motor drive system 100. Method 700 may be performed with fewer or more steps than shown in FIG. 7. Moreover, steps of method 700 may be omitted, repeated, performed in parallel, performed in a different order than shown in FIG. 7, or performed recursively. As one example, steps 710 and 712 may represent an embodiment for performing step 708, and may thus be performed at the same time as step 708.

Step 702 may include receiving a discharge command to discharge a DC link capacitor. For example, as described above with reference to FIG. 2, gate driver 131 and/or gate driver 141 may receive a discharge command DCD from control circuit 120.

Step 704 may include driving a first switch of a first phase of an inverter coupled to the DC link capacitor in an on-state. For example, as described above with reference to FIGS. 2-4, gate driver 131 may drive high-side switch 161 of first phase 151 of inverter 150 in an on state.

Step 706 may include sensing a discharge current through a second switch of the first phase of the inverter. For example, as described above with reference to FIGS. 2-4, hysteretic current-control circuit 145 may receive a sense current from sense-FET 171b that represents the discharge current through low-side switch 171 of the first phase 151 of inverter 150.

Step 708 may include hysteretically regulating the discharge current through the second switch of the first phase of the inverter based on a minimum-discharge-current threshold and a maximum-discharge current threshold. For example, as described above with reference to FIGS. 2-4, hysteretic current-control circuit 145 may regulate the discharge current through low-side switch 171 of the first phase 151 of inverter 150 based on the minimum-discharge-current threshold I_{DCD_MIN} and a maximum-discharge current threshold I_{DCD_MAX}.

In some embodiments, hysteretically regulating the discharge current through the second switch may include receiving a sense current representative of the discharge current, comparing a first mirrored sense-FET current against a first current threshold corresponding to the minimum-discharge-current threshold, and comparing a second mirrored sense-FET current against a second current threshold corresponding to the maximum-discharge-current threshold. For example, as described above with reference to FIGS. 2-4, current mirror circuit 301 of hysteretic current-control circuit 145 may receive and mirror a sense current from sense-FET 171b that is representative of the discharge current through low-side switch 171. First comparator 320 may compare a first mirrored sense-FET current against a first current threshold I_{DCD_L} corresponding to the minimum-discharge-current threshold I_{DCD_MIN}, and second comparator 330 may compare a second mirrored sense-FET current against second threshold I_{DCD_H} corresponding to a maximum-discharge current threshold I_{DCD_MAX}. Latch 340, PWM logic 350, current-starved pull-up circuit 360, and current-starved pull-down circuit 370 may in turn drive the gate of low-side switch 171 based on the outputs of first comparator 320 and second comparator 330 to regulate the discharge current as described above with reference to FIGS. 3-4.

As another example, and as described above with reference to FIGS. 5 and 6, hysteretic current-control circuit 146 may regulate the discharge current through low-side switch 171 of the first phase 151 of inverter 150 based on the minimum-discharge-current threshold I_{DCD_MIN} and the maximum-discharge current threshold I_{DCD_MAX}. In some embodiments, hysteretically regulating the discharge current through the second switch may include receiving a sense voltage representative of the discharge current and comparing the sense voltage against a first voltage threshold corresponding to the minimum-discharge-current threshold I_{DCD_MIN} and a second voltage threshold corresponding to the maximum-discharge-current threshold I_{DCD_MAX}. For example, as described above with reference to FIGS. 5 and 6, a sense voltage proportional to or representative of the discharge current through low-side switch 171 may be produced across sense resistor 510. The hysteretic voltage comparator 520 within hysteretic current-control circuit 146 may in turn compare the sense voltage produced across sense resistor 510 against a first voltage threshold V_{DCD_MIN} corresponding to the minimum-discharge-current threshold I_{DCD_MIN}, and against a second voltage threshold V_{DCD_MAX} corresponding to the maximum-discharge-current threshold I_{DCD_MAX}. Latch 340, PWM logic 350, current-starved pull-up circuit 360, and current-starved pull-down circuit 370 may in turn drive the gate of low-side switch 171 based on the V_{CMP_DCD} signal output by hysteretic voltage comparator 520 to regulate the discharge current.

Step 710 may include increasing a gate voltage of the second switch (low-side switch 171 for example) in response the discharge current crossing below the minimum-discharge-current threshold. For example, as described above with reference to FIGS. 3-4, and as part of hysteretically regulating the discharge current, hysteretic current-control circuit 145 may charge the gate capacitance of low-side switch 171 to increase the gate voltage of low-side switch 171 in response to the first comparator 320 detecting that the discharge current I_{D} crossed below the minimum-discharge-current threshold I_{DCD_MIN}. In some embodiments, increasing the gate voltage of the second switch (low-side switch 171 for example) may include driving the gate of the second switch with a current-starved pull-up circuit. For example, as described above with reference to FIGS. 3-4, in response the discharge current I_{D} crossing below the minimum-discharge-current threshold I_{DCD_MIN}, current-starved pull-up circuit 360 may slowly charge the gate capacitance of low-side switch 171 through resistor 241 to increase the gate voltage of low-side switch 171, thereby causing the discharge current I_{D} through low-side switch 171 to increase.

Step 712 may include decreasing the gate voltage of the second switch in response to the discharge current crossing above the maximum-discharge-current threshold. For example, as described above with reference to FIGS. 3-4, and as part of hysteretically regulating the discharge current, hysteretic current-control circuit 145 may discharge the gate capacitance of low-side switch 171 to decrease the gate voltage of low-side switch 171 in response to the second comparator 330 detecting that the discharge current I_{D} crossed above the maximum-discharge-current threshold I_{DCD_MIN}. In some embodiments, decreasing the gate voltage of the second switch (low-side switch 171 for example) may include driving the gate of the second switch with a current-starved pull-down circuit. For example, as described above with reference to FIGS. 3-4, in response the discharge current crossing above the maximum-discharge-current threshold I_{DCD_MAX}, current-starved pull-down circuit 370 may slowly discharge the gate capacitance of low-side switch 171 through resistor 242 to decrease the gate voltage of low-side switch 171, thereby causing the discharge current I_{D} through low-side switch 171 to decrease.

Step 714 may include driving the first switch and the second switch of the first phase in respective off-states in response to detecting a voltage of the DC link capacitor has crossed below a voltage threshold. For example, as described above with reference to FIG. 2, monitor circuit 122 may monitor the voltage of the DC voltage bus VBUS, and thereby the voltage of DC link capacitor 115. When monitor circuit 122 detects that VBUS has been discharged down to the discharge threshold V_{DCTH}, monitor circuit 122 may instruct control circuit 120 to conclude the discharge time. In turn, control circuit 120 may control gate driver 131 to drive high-side switch 161 in an off state, and may control gate driver 141 to drive low-side switch 171 in an off state.

Step 716 may include recording a discharge time required to discharge a DC link capacitor to a discharge threshold for each of a plurality of discharging cycles. Step 718 may include estimating a capacitance of the DC link capacitor based on the discharge current and a recorded discharge time. And step 720 may include producing an alert in response to change in an estimated capacitance of the DC link capacitor. For example, as described above with reference to FIG. 2, monitor circuit 122 may record a discharge time required for the discharge current to discharge the DC link capacitor 115 to the discharge threshold V_{DCTH} for each of a plurality of discharge cycles. In some embodiments, monitor circuit 122 may then estimate a capacitance of the DC link capacitor 115 based on the discharge current and a recorded discharge time. For example, the capacitance of DC link capacitor 115 may be expressed as C₁₁₅ = I_{D} x (dt/dV), where C₁₁₅is the capacitance value of DC link capacitor 115, I_{D} is the average discharge current, dt is the recorded discharge time, and dV is the voltage delta from the normal operating voltage (400 V for example) down to the discharge threshold V_{DCTH} (60 V for example). The average discharge current I_{D} may be represented by the average of known quantities for the minimum-discharge-current threshold I_{DCD_MIN} and the maximum-discharge-current threshold I_{DCD_MAX}. Further, dV may simply be the difference between the known quantities for the normal operating voltage and the discharge threshold V_{DCTH}. Accordingly, the capacitance of DC link capacitor 115 may be determined based on the recorded discharge time. A drop in the capacitance value of DC link capacitor 115 over time may indicate that the DC link capacitor 115 may soon fail. Accordingly, monitor circuit 122 may produce an alert in response to a change in an estimated capacitance of the DC link capacitor 115. Such an alert may prompt the user of the electric vehicle (or the entity responsible for maintenance of the electric vehicle) to replace DC link capacitor 115 before failure.

In addition to the controlled discharge of DC link capacitor 115 that may occur for example when the electric vehicle that includes motor drive system 100 is turned off, control circuit 120 may also initiate a controlled pre-charge of DC link capacitor 115 to re-charge DC link capacitor 115 prior to the electric vehicle turning back on and resuming operation. Such a controlled pre-charge of DC link capacitor 115 may prevent large, and potentially damaging, in-rush currents when switches 110 and 112 are turned fully on in order to couple battery 102 across the DC voltage bus VBUS and the system ground GND.

FIG. 8 illustrates a schematic diagram of components of a charge circuit within a motor drive system in accordance with embodiments of the present disclosure. Specifically, FIG. 8 illustrates further details of certain components within motor drive system 100 (shown in FIG. 1) that form a charge circuit configured to pre-charge DC link capacitor 115 in response to a charge command CHG.

As described above with reference to FIG. 1, switch 110 and switch 112 may be operated in an open state (for example, an off state) when the electric vehicle in which motor drive system 100 is turned off. For example, control circuit 120 may assert high-side breaker signal HS_BR at a logic-low level to instruct gate driver 111 to drive switch 110 in an off state. During this time, control circuit 120 may also assert low-side breaker signal LS_BR at a logic-low level to instruct gate driver 113 to drive switch 112 in an off state. Conversely, when the electric vehicle is operating, switch 110 and switch 112 may be operated in a fully-on state to couple battery 102 across VBUS and system ground. For example, control circuit 120 may assert high-side breaker signal HS_BR at a logic-high level to instruct gate driver 111 to drive switch 110 in a fully-on state. During this time, control circuit 120 may also assert the low-side breaker signal LS_BR at a logic-low level to instruct gate driver 113 to drive switch 112 in fully-on state. To prevent potentially damaging in-rush currents when the electric vehicle is turned on, the charge circuit within motor drive system 100 may first regulate a charge current through switch 110 to provide a controlled pre-charge of DC link capacitor 115 before driving switch 110 in the fully-on state.

As shown in FIG. 8, switch 110 may be coupled between a first terminal of battery 102 and a first terminal of DC link capacitor 115. For example, switch 110 may include a drain terminal to be coupled to battery 102, a source terminal to be coupled to DC link capacitor 115, and a gate terminal coupled to be driven by gate driver 111.

In some embodiments, switch 110 may include power-FET 110a and sense-FET 110b. Power-FET 110a may be configured at a size sufficient to handle the high voltage and high currents for driving motor 180 with power from battery 102. Sense-FET 110b may be sized at a ratio of 1:N relative to power-FET 110a, where N equals, for example, 10, 100, 1000, 10000, or more. In some embodiments, sense-FET 110b may be formed by one or more MOSFET cells monolithically integrated and/or laid out together with a plurality of MOSFET cells forming power-FET 110a. As shown in FIG. 8, the gate of sense-FET 110b may be coupled to the gate of power-FET 110a at gate input G, and the drain of sense-FET 110b may be coupled to the drain of power-FET 110a at drain node D, and the source of sense-FET 110b may be coupled to sense terminal CS. Sense-FET 110b may thus be configured to produce a sense current at the sense terminal CS that corresponds to the current through power-FET 110a. As described in further detail below, the sense current provided by sense-FET 110b may be utilized to sense, and thereby regulate, a charge current through switch 110.

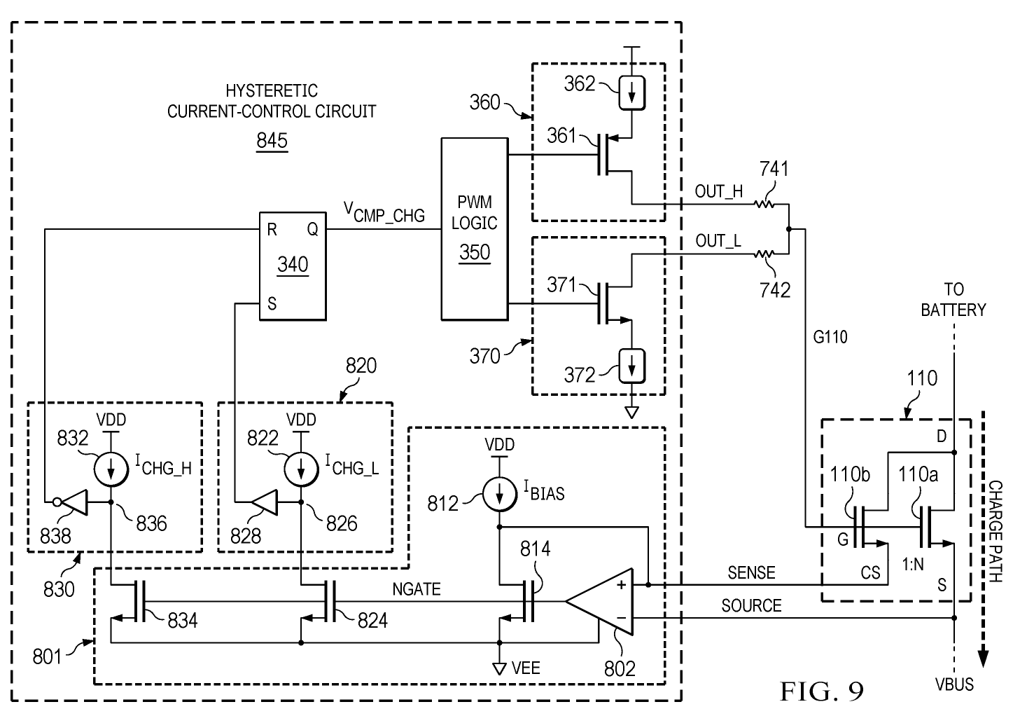

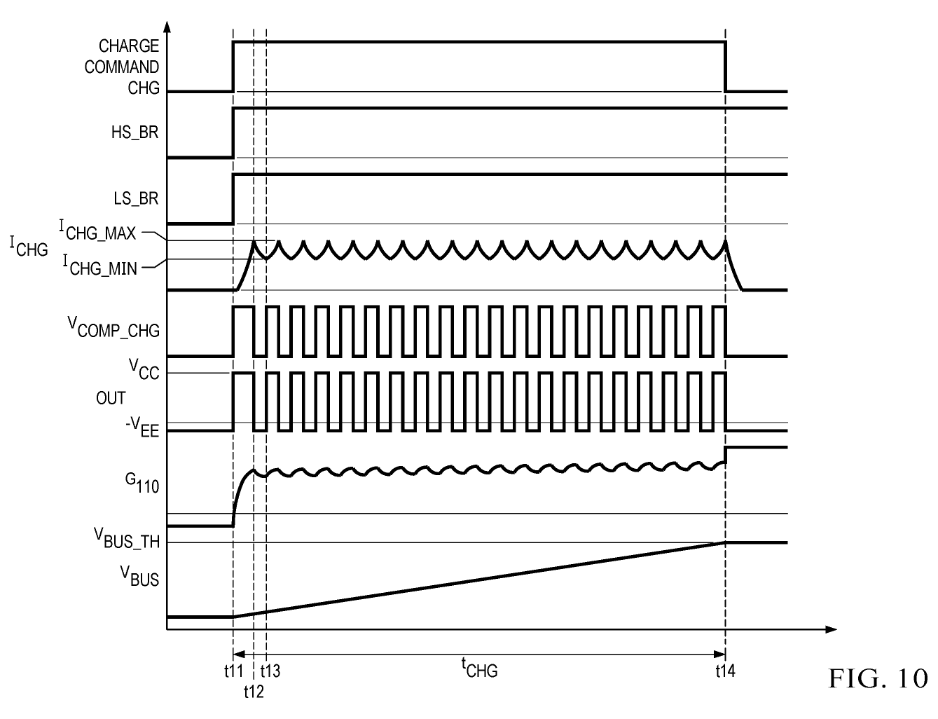

Gate driver 111 may include drive circuit 842, hysteretic current-control circuit 845, and an output configured to drive a gate terminal of switch 110. Drive circuit 842 may include logic circuit 843 and output circuit 149. Logic circuit 843 may be configured to receive a high-side breaker signal HS_BR and a charge command CHG from control circuit 120. Logic circuit 843 may control output circuit 844, which may include level shifters and/or buffers required to drive the gate of switch 110. As shown in FIG. 8, output circuit 844 may include a high output OUT_H which may drive the gate of switch 110 high via resistor 741, and may also include a low output OUT_L that may drive the gate of switch 110 low via resistor 742. During normal operation of the electric vehicle, logic circuit 843 may control output circuit 844 to drive switch 110 in a fully-on state based on the high-side breaker signal HS_BR. However, in response to a charge command CHG prior to operation of the electric vehicle, logic circuit 843 may disable output circuit 844, thereby allowing hysteretic current-control circuit 845 to take over control of the gate of switch 110. And as described in further detail below with reference to FIGS. 9 and 10, hysteretic current-control circuit 845 may be configured to, in response to the charge command CHG, regulate a charge current through switch 110 based on a minimum-charge-current threshold and a maximum-charge-current threshold.

FIG. 9 illustrates a schematic diagram of components of a charge circuit within a motor drive system in accordance with embodiments of the present disclosure. Specifically, FIG. 9 illustrates further details of hysteretic current-control circuit 845 and its operation with switch 110.

Hysteretic current-control circuit 845 may be implemented in any suitable fashion according to the operation described herein. As shown in FIG. 9, hysteretic current-control circuit 845 may include current mirror circuit 801, first comparator 820, second comparator 830, latch 340, PWM logic 350, current-starved pull-up circuit 360, and current-starved pull-down circuit 370.

Current mirror circuit 801 may be configured to mirror the sense current from the sense-FET 110b of switch 110. In some embodiments, current mirror circuit 801 may include amplifier 802, current source 812, and transistors 814, 824, and 834. Amplifier 802 may have a first input (for example, the negative “-” input) coupled to the source of power-FET 110a, and a second input (for example, the positive “+” input) coupled to the source of sense-FET 110b. Amplifier 802 may also have an output coupled to drive the gate of transistor 814 at node NGATE. As shown in FIG. 9, transistor 814 may have a gate coupled to be driven by the output of amplifier 802, a source coupled to voltage rail VEE, and a drain coupled to the second input of amplifier 802 and the source of sense-FET 110b. Accordingly, amplifier 802 may drive the gate of transistor 814 at the gate voltage required for transistor 814 to sink the sense current from sense-FET 110b. The feedback loop formed by transistor 814 back to the positive input of amplifier 802 may ensure that the voltage at the positive input of amplifier 802 (coupled to the source of sense-FET 110b) approximately equals the voltage at the negative input (coupled to the source of power-FET 110a), thereby ensuring a close match between the sense current through sense-FET 110b and the charge current through power-FET 110aat the designed 1:N ratio. In some embodiments, voltage rail VEE may be provided at a negative voltage relative to the source of power-FET 110a in order to provide sufficient voltage headroom for amplifier 802 to operate. Further, in some embodiments, current source 812 may provide a bias current I_{BIAS} to the node that couples together the drain of transistor 814 and the positive input of amplifier 802. The bias current I_{BIAS} may keep the feedback loop formed by amplifier 802 and transistor 814 biased, for example, during times of no sense current from sense-FET 110b.

As shown in FIG. 9, transistors 824 and 834 may each have a gate coupled to the same node NGATE as the gate of transistor 814, and may each have a source coupled to the same voltage rail VEE as transistor 814. Further, transistors 824 and 834 may be configured to match transistor 814. For example, in embodiments where transistor 814 is an NMOS transistor, transistors 824 and 834 may be formed by matching NMOS transistors. Accordingly, transistors 824 and 834 may each mirror the sense current from sense-FET 110b.

First comparator 820 may be configured to compare a first mirrored sense-FET current (produced at the drain of transistor 824) against a first current threshold I_{CHG_L} corresponding to the minimum-charge-current threshold, which is illustrated in FIG. 10 as I_{CHG_MIN}. For example, first comparator 820 may include current source 822 and buffer 828. Current source 822 may be coupled between voltage rail VDD and node 826, which may in turn be coupled to the drain of transistor 824. First comparator 820 may thus compare the first mirrored sense-FET current produced by transistor 824 against the first current threshold I_{CHG_L} produced by current source 822. The first current threshold I_{CHG_L} may correspond to the minimum-charge-current threshold I_{CHG_MIN} for the charge current through switch 110. For example, the first current threshold I_{CHG_L} may be scaled relative to the minimum-charge-current threshold at the same 1:N ratio as the scaling for the relative sizes of sense-FET 110b and power-FET 110a(or any other ratio further accounting for any scaling between transistors 814 and 824). In some embodiments, the first current threshold I_{CHG_L} may be further adjusted to account for any offsets to the first mirrored sense-FET current caused by the bias current I_{BIAS} in current mirror circuit 801. When the charge current through switch 110 is greater than the minimum-charge-current threshold I_{CHG_MIN,} the first mirrored sense-FET current produced by transistor 824 may in turn be greater than the first current threshold I_{CHG_L}, and thus the voltage at node 826 may go low to thereby cause buffer 828 to output a logic-low signal. Conversely, when the charge current through switch 110 is less than the minimum-charge-current threshold I_{CHG_MIN,} the first mirrored sense-FET current produced by transistor 824 may in turn be less than the first current threshold I_{CHG_L}, and thus the voltage at node 826 may go high to thereby cause buffer 828 to output a logic-high signal.

Second comparator 830 may be configured to compare a second mirrored sense-FET current (produced at the drain of transistor 834) against a second current threshold I_{CHG_H} corresponding to the maximum-charge-current threshold, which is illustrated in FIG. 10 as I_{CHG_MAX}. For example, second comparator 830 may include current source 832 and inverter 838. Current source 832 may be coupled between voltage rail VDD and node 836, which may in turn be coupled to the drain of transistor 834. Second comparator 830 may thus compare the second mirrored sense-FET current produced by transistor 834 against the second current threshold I_{CHG_H} produced by current source 832. The second current threshold I_{CHG_H} may correspond to the maximum-charge-current threshold I_{CHG_MAX} for the charge current through switch 110. For example, the second current threshold I_{CHG_H} may be scaled relative to the maximum-charge-current threshold at the same 1:N ratio as the scaling for the relative sizes of sense-FET 110b and power-FET 110a(or any other ratio further accounting for any scaling between transistors 814 and 834). In some embodiments, the second current threshold I_{CHG_H} may be further adjusted to account for any offsets to the second mirrored sense-FET current caused by the bias current I_{BIAS} in current mirror circuit 801. When the charge current through switch 110 is greater than the maximum-charge-current threshold I_{CHG_MAX,} the second mirrored sense-FET current produced by transistor 834 may in turn be greater than the second current threshold I_{CHG_H}, and thus the voltage at node 836 may go low to thereby cause inverter 838 to output a logic-high signal. Conversely, when the charge current through switch 110 is less than the maximum-charge-current threshold I_{CHG_MAX,} the second mirrored sense-FET current produced by transistor 834 may in turn be less than the second current threshold I_{CHG_H}, and thus the voltage at node 836 may go high to thereby cause inverter 838 to output a logic-low signal.

As shown in FIG. 9, latch 340 may include a set input S coupled to the output of first comparator 820, a reset input R coupled to the output of second comparator 830, and an output configured to provide a charge current comparison signal V_{CMP_CHG}. The charge current comparison signal V_{CMP_CHG} may be provided to PWM logic 350, which may in turn drive current-starved pull-up circuit 360 and current-starved pull-down circuit 370.

Current-starved pull-up circuit 360 may include transistor 361 and current-limiter 362. In some embodiments, transistor 361 may be a PMOS transistor. Current-limiter 362 may be coupled between supply rail VCC and transistor 361. Transistor 361 may have a source coupled to current-limiter 362 and the high output OUT_H of gate driver 111. In some embodiments, current-limiter 362 may be implemented by a current source, a resistor, or any other circuit element suitable to limit the pull-up current provided by transistor 361 to the gate of switch 110 when current-starved pull-up circuit 360 is enabled by PWM logic 350.

Current-starved pull-down circuit 370 may include transistor 371 and current-limiter 372. In some embodiments, transistor 371 may be an NMOS transistor. Current-limiter 372 may be coupled between VEE and transistor 371. Transistor 371 may have a source coupled to current-limiter 372 and the low output OUT_L of gate driver 111. In some embodiments, current-limiter 372 may be implemented by a current source, a resistor, or any other circuit element suitable to limit the pull-down current provided by transistor 371 to the gate of switch 110 when current-starved pull-down circuit 370 is enabled by PWM logic 350.

Current-starved pull-up circuit 360 may be configured to increase the gate volage of switch 110 in response to the charge current crossing below the minimum-charge-current threshold I_{CHG_MIN}. For example, as described above, when the charge current through switch 110 is below the minimum-charge-current threshold I_{CHG_MIN}, first comparator 820 may set latch 340, causing V_{CMP_CHG} to go high. When V_{CMP_CHG} goes high, PWM logic 350 may disable current-starved pull-down circuit 370, and may enable current-starved pull-up circuit 360. In turn, current-starved pull-up circuit 360 may charge the gate capacitance of switch 110 to thereby increase the gate voltage of switch 110. The charge current may in turn increase with the increased gate voltage.

Current-starved pull-down circuit 370 may be configured to decrease the gate volage of switch 110 in response to the charge current crossing above the maximum-charge-current threshold I_{CHG_MAX}. For example, as described above, when the charge current through switch 110 is above maximum-charge-current threshold I_{CHG_MAX}, second comparator 830 may reset latch 340, causing V_{CMP_CHG} to go low. When V_{CMP_CHG} goes low, PWM logic 350 may disable current-starved pull-up circuit 360, and may enable current-starved pull-down circuit 370 and. In turn, current-starved pull-down circuit 370 may discharge the gate capacitance of switch 110 to thereby reduce the gate voltage of switch 110. The charge current may in turn decrease with the decreased gate voltage.

FIG. 10 illustrates plot diagrams of waveforms within a motor drive system in accordance with embodiments of the present disclosure. Specifically, FIG. 10 illustrates waveforms showing the hysteretic control of the charge current provided by hysteretic current-control circuit 845 described above with reference to FIGS. 8 and FIG. 9.

As shown in FIG. 10, high-side breaker signal HS_BR and low-side breaker signal LS_BR may both be at logic-low levels before time t11 to force gate driver 111 and gate driver 113 to drive switch 110 and switch 112 in respective off-states. At time t11, control circuit 120 may assert a charge command CHG to initiate a controlled pre-charge of DC link capacitor 115. For example, at time t1, control circuit 120 may assert LS_BR at a logic-high level to instruct gate driver 113 to drive switch 112 in an on state. Control circuit 120 may also assert HS_BR and the CHG command at logic high levels. During the time that both HS_BR and CHG are high, the output of gate driver 111 may be controlled by hysteretic current-control circuit 845. The hysteretic current-control circuit 845 within gate driver 141 may thus drive the switch 110 to regulate the charge current that may flow from battery 102, through switch 110, and to DC link capacitor 115.

With the charge current I_{CHG} at time t11 below the minimum-charge-current threshold I_{CHG_MIN}, first comparator 820 may set latch 340, causing V_{CMP_CHG} to go high and thereby enabling current-starved pull-up circuit 360 to slowly charge the gate capacitance of switch 110 to increase the gate voltage of switch 110. As shown in FIG. 10, the charge current I_{CHG} will increase as the gate voltage of switch 110 increases.

When the charge current I_{CHG} reaches and crosses just above the maximum-charge-current threshold I_{CHG_MAX} at time t12, second comparator 830 may reset latch 340, causing V_{CMP_CHG} to go low. In response, PWM logic 350 may disable current-starved pull-up circuit 360 and enable current-starved pull-down circuit 370. Accordingly, current-starved pull-down circuit 370 may discharge the gate capacitance of switch 110 to thereby reduce the gate voltage of switch 110. As shown in FIG. 10, the charge current I_{CHG} will decrease as the gate voltage of switch 110 decreases. Subsequently, when the charge current I_{CHG} reaches and crosses just below the minimum-charge-current threshold I_{CHG_MIN} at time t13, first comparator 820 may again set latch 840, causing V_{CMP_CHG} to go high. In response, PWM logic 350 may disable current-starved pull-down circuit 370 and enable current-starved pull-up circuit 360. Accordingly, current-starved pull-up circuit 360 may charge the gate capacitance of switch 110 to thereby increase the gate voltage of switch 110.

As shown in FIG. 10, the DC bus voltage VBUS will increase as the charge current I_{CHG} cyclically varies between the minimum-charge-current threshold I_{CHG_MIN} and the maximum-charge-current threshold I_{CHG_MAX} and thereby charges DC link capacitor 115. The charge period t_{CHG} may last from time t11 to the time t14 when the DC bus voltage VBUS reaches the charge threshold V_{BUS_TH}. The charge threshold V_{BUS_TH} may be set to be equal to or approximately equal to the desired operating voltage for VBUS, for example 400 V or 800 V. In some embodiments, gate driver 111 may be configured to drive switch 110 in a fully-on state in response to the voltage of DC link capacitor 115 (and thus VBUS) reaching and/or crossing above the charge threshold V_{BUS_TH}. For example, as described in further detail below, monitor circuit 122 may monitor VBUS and send a signal to inform control circuit 120 when VBUS has reached or crossed above the charge threshold V_{BUS_TH}. Control circuit 120 may in turn de-assert the charge command CHG as shown at time t14 in FIG. 10. In response to the de-assertion of the charge command CHG at time t14, and the continued assertion of HS_BR, the hysteretic current-control circuit 845 within gate driver 111 may be disabled, and the drive circuit 842 within gate driver 111 may drive the gate of switch 110 to a higher voltage (for example, at the upper supply rail of the gate driver 111) to drive switch 110 in a fully-on state.

As shown in FIG. 8, the charge circuit within motor drive system 100 may include monitor circuit 122. Monitor circuit 122 may be implemented in any suitable fashion according to the functionality described herein. In some embodiments, monitor circuit 122 may be implemented as a separate block from control circuit 120. In other embodiments, monitor circuit 122 may be incorporated within control circuit 120. Monitor circuit 122 may provide multiple functions. In some embodiments, monitor circuit 122 may monitor VBUS, and thereby the voltage of the DC link capacitor 115 coupled to VBUS. When monitor circuit 122 detects that VBUS has been pre-charged up to the charge threshold V_{CHG}, monitor circuit 122 may instruct control circuit 120 to conclude the regulated pre-charging of DC link capacitor 115. In turn, control circuit 120 may de-assert the charge command and instruct gate driver 111 to drive switch 110 in a fully-on state.

Monitor circuit 122 may also be configured to record a charge time required for the charge current I_{CHG} to pre-charge the DC link capacitor 115 to the charge threshold V_{CHG} for each of a plurality of charge cycles. Monitor circuit 122 may then utilize this information to monitor the health of DC link capacitor 115. In some embodiments, monitor circuit 122 may be configured to estimate a capacitance of the DC link capacitor 115 based on the charge current and a recorded charge time. For example, the capacitance of DC link capacitor 115 may be expressed as C₁₁₅ = I_{CHG} x (dt/dV), where C₁₁₅is the capacitance value of DC link capacitor 115, I_{CHG} is the average charge current, dt is the recorded charge time, and dV is the voltage delta from the starting voltage (for example, the discharge threshold of 60 V) up to the normal operating voltage (400 V for example). The average charge current I_{CHG} may be represented by the average of known quantities for the minimum-charge-current threshold I_{CHG_MIN} and the maximum-charge-current threshold I_{CHG_MAX}. Further, dV may simply be the difference between the known quantities for the normal operating voltage and the discharge threshold V_{DCTH}. Accordingly, the capacitance of DC link capacitor 115 may be determined based on the recorded charge time. A drop in the capacitance value of DC link capacitor 115 over time may indicate that the DC link capacitor 115 may soon fail. Accordingly, monitor circuit 122 may also be configured to produce an alert in response to a change in an estimated capacitance of the DC link capacitor 115. Such an alert may prompt the user of the electric vehicle (or the entity responsible for maintenance of the electric vehicle) to replace DC link capacitor 115 before failure.

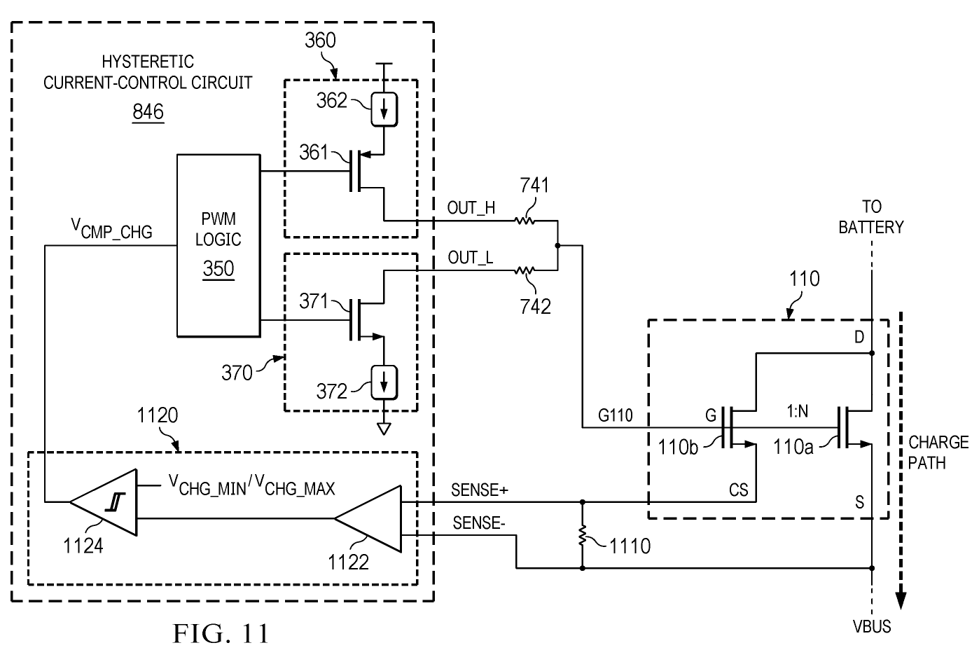

FIG. 11 illustrates a schematic diagram of components of a charge circuit within a motor drive system in accordance with embodiments of the present disclosure. Specifically, FIG. 11 illustrates details of hysteretic current-control circuit 846, which may serve as an alternative implementation of hysteretic current-control circuit 845 described above with reference to FIGS. 8-10.

As shown in FIG. 11, sense resistor 1110 may be coupled to produce a sense voltage based on a sense current from sense-FET 110b. For example, sense resistor 1110 may be coupled between the source of sense-FET 110b and VBUS, and may thus produce a sense voltage based on the sense current from sense-FET 110b. The sense voltage may thus correspond to the charge current through switch 110. And as described below, hysteretic current-control circuit 846 may utilize the sense voltage to hysteretically regulate the charge current through switch 110.

Hysteretic current-control circuit 846 may include a hysteretic voltage comparator 1120, PWM logic 350, current-starved pull-up circuit 360, and current-starved pull-down circuit 370. Hysteretic voltage comparator 1120 may be configured to compare the sense voltage produced by sense resistor 1110 against a first voltage threshold V_{CHG_MIN} corresponding to the minimum-charge-current threshold I_{CHG_MIN}, and against a second voltage threshold V_{CHG_MAX} corresponding to the maximum-charge-current threshold I_{CHG_MAX}.

In some embodiments, hysteretic voltage comparator 1120 may include sense amplifier 1122 and hysteretic comparator 1124. Sense amplifier 1122 may amplify and/or buffer the sense voltage produced across sense resistor 1110, and may provide an output to hysteretic comparator 1124. Hysteretic comparator 1124 may have a built-in hysteresis, and may thus compare the output of sense amplifier 1122 against both of the first voltage threshold V_{CHG_MIN} the second voltage threshold V_{CHG_MAX} to produce a charge current comparison signal V_{CMP_CHG}.

The charge current comparison signal V_{CMP_CHG} may drive PWM logic 350, and thus current-starved pull-up circuit 360 and current-starved pull-down circuit 370, in a similar manner as described above for hysteretic current-control circuit 845 with reference to FIGS. 9-10. For example, when the charge current I_{CHG} reaches and crosses just above the maximum-charge-current threshold I_{CHG_MAX}, hysteretic voltage comparator 1120 may assert V_{CMP_CHG} at a logic low level. In response, PWM logic 350 may disable current-starved pull-up circuit 360 and enable current-starved pull-down circuit 370. Accordingly, current-starved pull-down circuit 370 may discharge the gate capacitance of switch 110 to thereby reduce the gate voltage of switch 110. As shown in FIG. 10, the charge current I_{CHG} will decrease as the gate voltage of the switch 110 decreases. Subsequently, when the charge current I_{CHG} reaches and crosses just below the minimum-charge-current threshold I_{CHG_MIN}, hysteretic voltage comparator 1120 may assert V_{CMP_CHG} at a logic high level. In response, PWM logic 350 may disable current-starved pull-down circuit 370 and enable current-starved pull-up circuit 360. Thus, current-starved pull-up circuit 360 may charge the gate capacitance of switch 110 to thereby increase the gate voltage of switch 110. Accordingly, hysteretic current-control circuit 846 may hysteretically regulate the charge current between the minimum-charge-current threshold I_{CHG_MIN} and the maximum-charge-current threshold I_{CHG_MAX} to thereby charge DC link capacitor 115.

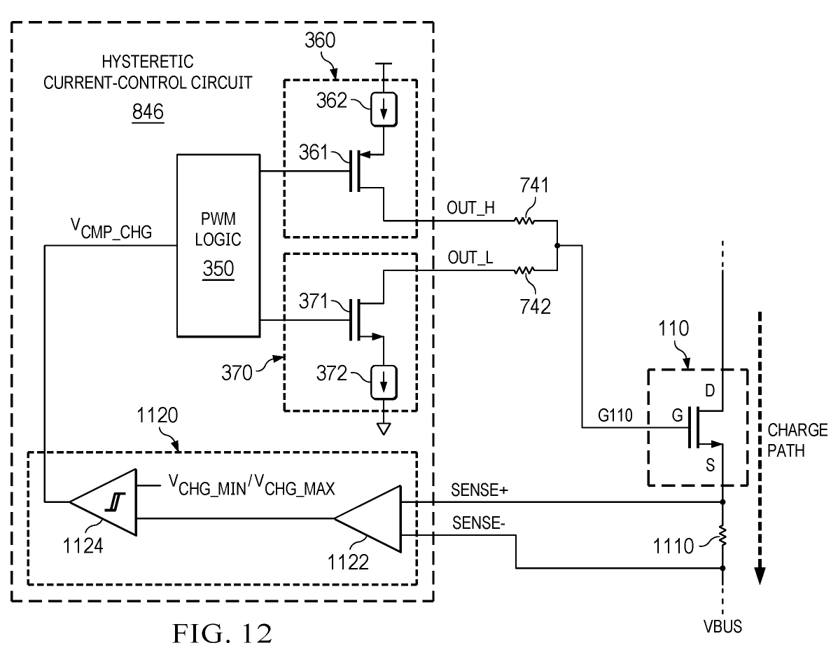

FIG. 12 illustrates a schematic diagram of components of a charge circuit within a motor drive system in accordance with embodiments of the present disclosure. Specifically, FIG. 12 illustrates an alternative arrangement for sense resistor 1110 and hysteretic current-control circuit 846 relative to the arrangement illustrated in FIG. 11.

As shown in FIG. 12, some embodiments of switch 110 may include a power-FET alone, instead of both a sense-FET integrated with a power-FET. For such embodiments, sense resistor 1110 may be coupled in series with switch 110 to produce a sense voltage proportional to the charge current. When placed directly in the charge path as shown in FIG. 12, sense resistor 1110 may be set to a low resistance value to reduce resistive loss that may otherwise occur when switch 110 is driven in a fully-on state during normal operation of the electric vehicle.

In a similar manner as described above with reference to FIG. 11, hysteretic voltage comparator 1120 may compare the sense voltage produced by sense resistor 1110 against a first voltage threshold V_{CHG_MIN} corresponding to the minimum-charge-current threshold I_{CHG_MIN}, and against a second voltage threshold V_{CHG_MAX} corresponding to the maximum-charge-current threshold I_{CHG_MAX}. Accordingly, hysteretic current-control circuit 846 may hysteretically regulate the charge current I_{CHG} between the minimum-charge-current threshold I_{CHG_MIN} and the maximum-charge-current threshold I_{CHG_MAX} to thereby charge the DC link capacitor 115 coupled to the DC voltage bus VBUS.

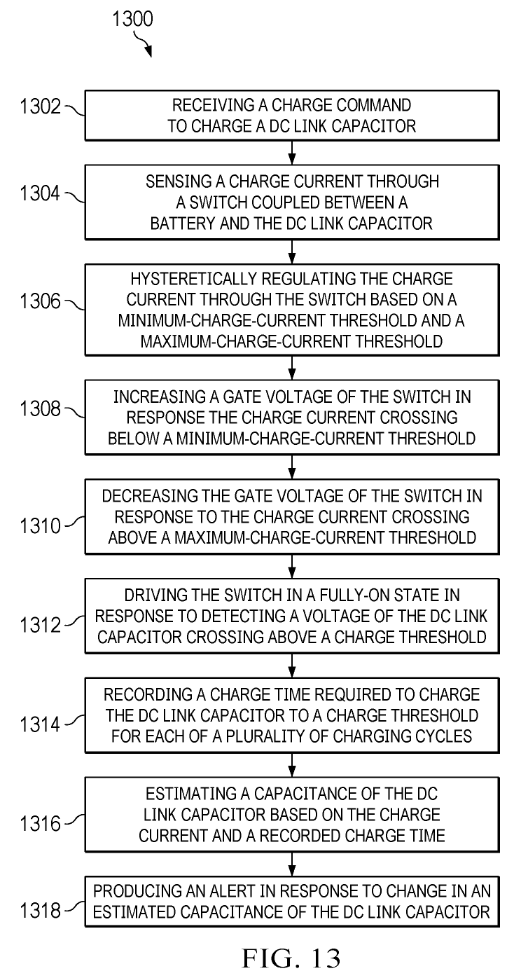

FIG. 13 illustrates a method 1300 for controlling operation of a motor drive system in accordance with embodiments of the present disclosure. Method 1300 may be performed by any suitable mechanism, such as control circuit 120 alone or in combination with other elements of motor drive system 100. Method 1300 may be performed with fewer or more steps than shown in FIG. 13. Moreover, steps of method 1300 may be omitted, repeated, performed in parallel, performed in a different order than shown in FIG. 13, or performed recursively. As one example, steps 1308 and 1310 may represent an embodiment for performing step 1306, and may thus be performed at the same time as step 1306.

Step 1302 may include receiving a charge command to charge a DC link capacitor. For example, as described above with reference to FIG. 9, gate driver 111 may receive a charge command CHG from control circuit 120 to control the pre-charge of DC link capacitor 115 prior to switch 110 being driven in a fully-on state to couple battery 102 to the DC voltage bus VBUS and DC link capacitor 115.

Step 1304 may include sensing a charge current through a switch coupled between a battery and the DC link capacitor. For example, as described above with reference to FIGS. 8-10, hysteretic current-control circuit 845 may receive a sense current from sense-FET 110b that represents the charge current from battery 102, through switch 110, and to DC link capacitor 115.

Step 1306 may include hysteretically regulating the charge current through the switch based on a minimum-charge-current threshold and a maximum-charge-current threshold. For example, as described above with reference to FIGS. 8-10, hysteretic current-control circuit 845 may regulate the charge current through switch 110 based on the minimum-charge-current threshold I_{CHG_MIN} and a maximum-charge current threshold I_{CHG_MAX}.

In some embodiments, hysteretically regulating the charge current through the second switch may include receiving a sense current representative of the charge current through the switch, comparing a first mirrored sense-FET current against a first current threshold corresponding to the minimum-charge-current threshold, and comparing a second mirrored sense-FET current against a second current threshold corresponding to the maximum-charge-current threshold. For example, as described above with reference to FIGS. 8-10, current mirror circuit 801 of hysteretic current-control circuit 845 may receive and mirror a sense current from sense-FET 110b that is representative of the charge current through switch 110. First comparator 820 may compare a first mirrored sense-FET current against a first current threshold I_{CHG_L} corresponding to the minimum-charge-current threshold I_{CHG_MIN}, and second comparator 830 may compare a second mirrored sense-FET current against second threshold I_{CHG_H} corresponding to a maximum-charge current threshold I_{CHG_MAX}. Latch 340, PWM logic 350, current-starved pull-up circuit 360, and current-starved pull-down circuit 370 may in turn drive the gate of switch 110 based on the outputs of first comparator 820 and second comparator 830 to regulate the charge current as described above with reference to FIGS. 9-10.

As another example, and as described above with reference to FIGS. 11 and 12, hysteretic current-control circuit 846 may regulate the charge current through switch 110 based on the minimum-charge-current threshold I_{CHG_MIN} and the maximum-charge current threshold I_{CHG_MAX}. In some embodiments, hysteretically regulating the charge current through the switch may include receiving a sense voltage representative of the charge current and comparing the sense voltage against a first voltage threshold corresponding to the minimum-charge-current threshold I_{CHG_MIN} and a second voltage threshold corresponding to the maximum-charge-current threshold I_{CHG_MAX}. For example, as described above with reference to FIGS. 11 and 12, a sense voltage proportional to or representative of the charge current through switch 110 may be produced across sense resistor 1110. The hysteretic voltage comparator 1120 within hysteretic current-control circuit 846 may in turn compare the sense voltage produced across sense resistor 1110 against the first voltage threshold V_{CHG_MIN} corresponding to the minimum-charge-current threshold I_{CHG_MIN}, and against the second voltage threshold V_{CHG_MAX} corresponding to the maximum-charge-current threshold I_{CHG_MAX}. Latch 340, PWM logic 350, current-starved pull-up circuit 360, and current-starved pull-down circuit 370 may in turn drive the gate of switch 110 based on the V_{CMP_CHG} signal output by hysteretic voltage comparator 1120 to regulate the charge current.

Step 1308 may include increasing a gate voltage of the switch in response the charge current crossing below a minimum-charge-current threshold. For example, as described above with reference to FIGS. 9-10, and as part of hysteretically regulating the charge current, hysteretic current-control circuit 845 may charge the gate capacitance of switch 110 to increase the gate voltage of switch 110 in response to the first comparator 820 detecting that the charge current I_{CHG} crossed below the minimum-charge-current threshold I_{CHG_MIN}. In some embodiments, increasing the gate voltage of switch 110 may include driving the gate of switch 110 with a current-starved pull-up circuit. For example, as described above with reference to FIGS. 9-10, in response the charge current I_{CHG} crossing below the minimum-charge-current threshold I_{CHG_MIN}, current-starved pull-up circuit 360 may slowly charge the gate capacitance of switch 110 through resistor 741 to increase the gate voltage of switch 110, thereby causing the charge current I_{CHG} through switch 110 to increase.

Step 1310 may include decreasing the gate voltage of the switch in response to the charge current crossing above the maximum-charge-current threshold. For example, as described above with reference to FIGS. 9-10, and as part of hysteretically regulating the charge current, hysteretic current-control circuit 845 may discharge the gate capacitance of switch 110 to decrease the gate voltage of switch 110 in response to the second comparator 830 detecting that the charge current I_{CHG} crossed above the maximum-charge-current threshold I_{CHG_MIN}. In some embodiments, decreasing the gate voltage of the switch 110 may include driving the gate of switch 110 with a current-starved pull-down circuit. For example, as described above with reference to FIGS. 6-10, in response the charge current I_{CHG} crossing above the maximum-charge-current threshold I_{CHG_MAX}, current-starved pull-down circuit 370 may slowly discharge the gate capacitance of switch 110 through resistor 742 to decrease the gate voltage of switch 110, thereby causing the charge current I_{CHG} through switch 110 to decrease.

Step 1312 may include driving the switch in a fully-on state in response to detecting a voltage of the DC link capacitor crossing above a charge threshold. For example, as described above with reference to FIG. 8, monitor circuit 122 may monitor the voltage of the DC voltage bus VBUS, and thereby the voltage of DC link capacitor 115. When monitor circuit 122 detects that DC link capacitor 115 has been charged up to the charge threshold V_{CHG}, monitor circuit 122 may instruct control circuit 120 to conclude the charge period t_{CHG}. In turn, control circuit 120 may control gate driver 111 to drive switch in a fully-on state to couple battery 102 to the DC link capacitor 115.

Step 1314 may include recording a charge time required to charge the DC link capacitor to a charge threshold for each of a plurality of charging cycles. Step 1316 may include estimating a capacitance of the DC link capacitor based on the charge current and a recorded charge time. And step 1318 may include producing an alert in response to change in an estimated capacitance of the DC link capacitor. For example, as described above with reference to FIG. 8, monitor circuit 122 may record a charge time required for the charge current I_{CHG} to charge the DC link capacitor 115 to the charge threshold V_{BUS_TH} for each of a plurality of charge cycles. In some embodiments, monitor circuit 122 may then estimate a capacitance of the DC link capacitor 115 based on the charge current and a recorded charge time. For example, the capacitance of DC link capacitor 115 may be expressed as C₁₁₅ = I_{CHG} x (dt/dV), where C₁₁₅is the capacitance value of DC link capacitor 115, I_{CHG} is the average charge current, dt is the recorded charge time, and dV is the voltage delta from the starting voltage (for example, the discharge threshold VDCTH of 60 V) up to the charge threshold V_{BUS_TH}. The average charge current I_{CHG} may be represented by the average of known quantities for the minimum-charge-current threshold I_{CHG_MIN} and the maximum-charge-current threshold I_{CHG_MAX}. Further, dV may simply be the difference between the known quantities for the initial bus voltage (for example the voltage of discharge threshold V_{DCTH}) and the normal operating voltage (for example 400V). Accordingly, the capacitance of DC link capacitor 115 may be determined based on the recorded charge time. A drop in the capacitance value of DC link capacitor 115 over time may indicate that the DC link capacitor 115 may soon fail. Accordingly, monitor circuit 122 may produce an alert in response to a change in an estimated capacitance of the DC link capacitor 115. Such an alert may prompt the user of the electric vehicle (or the entity responsible for maintenance of the electric vehicle) to replace DC link capacitor 115 before failure.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

1. A motor drive system comprising:
a DC link capacitor coupled to a DC voltage bus;
an inverter having multiple phases that each include a first switch and a second switch coupled in series between the DC voltage bus and system ground;
a first gate driver configured to drive the first switch of a first phase of the inverter in an on-state in response to a discharge command; and
a second gate driver including a hysteretic current-control circuit configured to, in response to the discharge command, regulate a discharge current through the second switch of the first phase of the inverter based on a minimum-discharge-current threshold and a maximum-discharge-current threshold.

2. The motor drive system of claim 1, wherein the hysteretic current-control circuit includes:
a current-starved pull-up circuit configured to increase a gate voltage of the second switch in response to the discharge current crossing below the minimum-discharge-current threshold; and
a current-starved pull-down circuit configured to decrease the gate voltage of the second switch in response to the discharge current crossing above the maximum-discharge-current threshold.

3. The motor drive system of claim 1, wherein:
the second switch of the first phase includes a sense-FET configured to provide a sense current representative of the discharge current through the second switch; and
the hysteretic current-control circuit includes:
a current mirror circuit configured to mirror the sense current from the sense-FET of the second switch;
a first comparator configured to compare a first mirrored sense-FET current against a first current threshold corresponding to the minimum-discharge-current threshold; and
a second comparator configured to compare a second mirrored sense-FET current against a second current threshold corresponding to the maximum-discharge-current threshold.

4. The motor drive system of claim 1, further comprising:
a sense resistor coupled to produce a sense voltage based on a sense current from a sense-FET of the second switch; and
wherein the hysteretic current-control circuit includes a hysteretic voltage comparator configured to compare the sense voltage against a first voltage threshold corresponding to the minimum-discharge-current threshold and a second voltage threshold corresponding to the maximum-discharge-current threshold.

5. The motor drive system of claim 1, further comprising:
a sense resistor coupled in series with the second switch to produce a sense voltage proportional to the discharge current; and
wherein the hysteretic current-control circuit includes a hysteretic voltage comparator configured to compare the sense voltage against a first voltage threshold corresponding to the minimum-discharge-current threshold and a second voltage threshold corresponding to the maximum-discharge-current threshold.

6. The motor drive system of claim 1, wherein the first gate driver and the second gate driver are configured to respectively drive the first switch and the second switch of the first phase in respective off states in response to a voltage of the DC link capacitor crossing below a discharge threshold.

7. The motor drive system of claim 1, further comprising a monitor circuit configured to record a discharge time required for the discharge current to discharge the DC link capacitor to a discharge threshold for each of a plurality of discharge cycles.

8. The motor drive system of claim 7, wherein the monitor circuit is further configured to estimate a capacitance of the DC link capacitor based on the discharge current and a recorded discharge time, and to produce an alert in response to change in an estimated capacitance of the DC link capacitor.

9. A control circuit comprising:
a first gate driver configured to drive a first switch of a first phase of an inverter in an on-state in response to a discharge command; and
a second gate driver including a hysteretic current-control circuit configured to, in response to the discharge command, regulate a discharge current through a second switch of the first phase of the inverter based on a minimum-discharge-current threshold and a maximum-discharge-current threshold.

10. The control circuit of claim 9, wherein the hysteretic current-control circuit includes:
a current-starved pull-up circuit configured to increase a gate voltage of the second switch in response to the discharge current crossing below the minimum-discharge-current threshold; and
a current-starved pull-down circuit configured to decrease the gate voltage of the second switch in response to the discharge current crossing above the maximum-discharge-current threshold.

11. The control circuit of claim 9, wherein the hysteretic current-control circuit includes:
a current mirror circuit configured to mirror a sense current from a sense-FET of the second switch;
a first comparator configured to compare a first mirrored sense-FET current against a first current threshold corresponding to the minimum-discharge-current threshold; and
a second comparator configured to compare a second mirrored sense-FET current against a second current threshold corresponding to the maximum-discharge-current threshold.

12. The control circuit of claim 9, wherein the hysteretic current-control circuit includes a hysteretic voltage comparator configured to compare a sense voltage representative of the discharge current against a first voltage threshold corresponding to the minimum-discharge-current threshold and a second voltage threshold corresponding to the maximum-discharge-current threshold.

13. A method of controlling operation of a motor drive system:
receiving a discharge command to discharge a DC link capacitor;
driving a first switch of a first phase of an inverter coupled to the DC link capacitor in an on-state;
sensing a discharge current through a second switch of the first phase of the inverter; and
hysteretically regulating the discharge current through the second switch of the first phase of the inverter based on a minimum-discharge-current threshold and a maximum-discharge-current threshold.

14. The method of claim 13, wherein hysteretically regulating the discharge current through the second switch comprises:
increasing a gate voltage of the second switch in response the discharge current crossing below the minimum-discharge-current threshold; and
decreasing the gate voltage of the second switch in response to the discharge current crossing above the maximum-discharge-current threshold.

15. The method of claim 14, wherein:
increasing the gate voltage of the second switch comprises driving a gate of the second switch with a current-starved pull-up circuit; and
decreasing the gate voltage of the second switch comprises driving the gate of the second switch with a current-starved pull-down circuit.

16. The method of claim 13, wherein hysteretically regulating the discharge current through the second switch comprises:
receiving a sense current representative of the discharge current;
comparing a first mirrored sense-FET current against a first current threshold corresponding to the minimum-discharge-current threshold; and
comparing a second mirrored sense-FET current against a second current threshold corresponding to the maximum-discharge-current threshold.

17. The method of claim 13, wherein hysteretically regulating the discharge current through the second switch comprises:
receiving a sense voltage representative of the discharge current; and
comparing the sense voltage against a first voltage threshold corresponding to the minimum-discharge-current threshold and a second voltage threshold corresponding to the maximum-discharge-current threshold.

18. The method of claim 13, further comprising driving the first switch and the second switch of the first phase in respective off-states in response to detecting a voltage of the DC link capacitor has crossed below a voltage threshold.

19. The method of claim 13, further comprising recording a discharge time required to discharge the DC link capacitor to a discharge threshold for each of a plurality of discharging cycles.

20. The method of claim 19, further comprising:
estimating a capacitance of the DC link capacitor based on the discharge current and a recorded discharge time; and
producing an alert in response to change in an estimated capacitance of the DC link capacitor.
